(19) United States
(12) Patent Application Publication
(10) Pub. No.: US 2016/0020365 A1
(43) Pub. Date: Jan. 21, 2016

(54) OPTOELECTRONIC COMPONENT

(71) Applicant: OSRAM OPTO SEMICONDUCTORS GMBH, Regensburg (DE)

(72) Inventors: Michael BRANDL, Mintraching (DE); Stefan GRÖTSCH, Bad Abbach (DE)

(21) Appl. No.: 14/774,798

(22) PCT Filed: Feb. 25, 2014
(86) PCT No.: PCT/EP2014/053599

§ 371 Date: Sep. 11, 2015

(30) Foreign Application Priority Data
Mar. 12, 2013 (DE) 10 2013 204 291.4

(51) Int. Cl. H01L 33/46; H01L 25/075; H01L 33/50

(52) U.S. Cl. CPC H01L 33/46; H01L 33/505; H01L 25/0753

(57) ABSTRACT

An optoelectronic component includes a carrier substrate, a single optoelectronic semiconductor chip arranged on the carrier substrate, an emission surface that emits light radiation which is part of a front side of the optoelectronic component, and a reflective layer adjacent to the emission surface at the front side of the optoelectronic component, wherein the emission surface is arranged such that the emission surface forms a part of an edge of the front side of the optoelectronic component.

### TECHNICAL FIELD

This disclosure relates to an optoelectronic component comprising a carrier substrate, a single optoelectronic semiconductor chip arranged on the carrier substrate, an emission surface for emitting light radiation, which is part of a front side of the optoelectronic component, and a reflective layer adjacent to the emission surface at the front side of the optoelectronic component. The disclosure also relates to a lighting device comprising a plurality of optoelectronic components.

This application claims the priority of German Patent Application 10 2013 204 291.4, the disclosure content of which is incorporated here by reference.

### BACKGROUND

Optoelectronic components may comprise an optoelectronic semiconductor chip that generates light radiation and a luminescent material for partial or complete conversion of the generated light radiation. In one known configuration, a conversion element which is in the shape of a platelet and comprises a conversion material is arranged directly on the semiconductor chip. The semiconductor chip is, in particular, a light emitting diode chip, or LED chip. The conversion element provides a front-side emission surface, through which light radiation can be emitted.

In various illumination applications, for example, vehicle headlamps, alignment of a plurality of LED chips is used so that a high light flux can be achieved. Conventionally, a small spacing of the LED chips and, therefore, of the luminous emission surfaces, is desired to obtain a uniform light pattern. The LED light sources should at the same time be flexibly usable to avoid expensive provision of many variants of lighting devices.

A small spacing can be implemented with the aid of components in which a plurality of LED chips is arranged on a common carrier substrate. Regions between the chips and the conversion elements, and around these, are generally provided with a reflective layer in the form of encapsulation. In this way, it is possible to achieve the effect that light radiation is emitted only through the front-side luminous surfaces of the conversion element. This approach, however, compromises flexibility.

High flexibility is possible by using small components in which, respectively, an individual LED chip is arranged on its own carrier substrate. The LED chip and the conversion element arranged thereon and, therefore, the front-side emission surface of the conversion element, are in this case as well conventionally enclosed by reflective encapsulation to emit light radiation only at the emission surface. Such single-chip components may be arranged on a relatively large carrier or a circuit board.

It is disadvantageous that, when using conventional single-chip components, their luminous surfaces, in contrast to the configuration described above with a plurality of chips, can only be positioned with a relatively large spacing from one another. This is due to edge regions of the components which, for example, are configured with a reflective encapsulation to achieve optical stability, and to a spacing required for the fitting and soldering of the individual components. In other words, high flexibility is achieved at the cost of the spacing of the luminous emission surfaces.

It could therefore be helpful to provide a solution for an improved optoelectronic component.

### SUMMARY

We provide an optoelectronic component including a carrier substrate, a single optoelectronic semiconductor chip arranged on the carrier substrate, an emission surface that emits light radiation which is part of a front side of the optoelectronic component, and a reflective layer adjacent to the emission surface at the front side of the optoelectronic component, wherein the emission surface is arranged such that the emission surface forms a part of an edge of the front side of the optoelectronic component.

We also provide the optoelectronic component including a carrier substrate, a single optoelectronic semiconductor chip arranged on the carrier substrate, an emission surface that emits light radiation which is part of a front side of the optoelectronic component, and a reflective layer adjacent to the emission surface at the front side of the optoelectronic component, wherein the emission surface is arranged such that the emission surface forms a part of an edge of the front side of the optoelectronic component and wherein the plurality of side walls is planar.

We further provide an optoelectronic component including a carrier substrate, a single optoelectronic semiconductor chip arranged on the carrier substrate, an emission surface that emits light radiation, which is part of a front side of the optoelectronic component, and a reflective layer adjacent to the emission surface at the front side of the optoelectronic component, wherein the emission surface has a cross-sectional width at least as large as a cross-sectional width of a rear side, opposite to the front side, of the optoelectronic component.

We also further provide a lighting device including a carrier and a group of a plurality of optoelectronic components including a carrier substrate, a single optoelectronic semiconductor chip arranged on the carrier substrate, an emission surface that emits light radiation, which is part of a front side of the optoelectronic component, and a reflective layer adjacent to the emission surface at the front side of the optoelectronic component, wherein the emission surface has a cross-sectional width at least as large as a cross-sectional width of a rear side, opposite to the front side, of the optoelectronic component, wherein the optoelectronic components of the group are arranged in a row next to one another on the carrier, and wherein, in relation to an extent direction of the row, for each of the optoelectronic components of the group the cross-sectional width of the emission surface is at least as large as the cross-sectional width of the rear side.

### BRIEF DESCRIPTION OF THE DRAWINGS

FIGS. 1 and 2 show a schematic lateral sectional representation and a schematic perspective representation of an optoelectronic component comprising a conversion element arranged in the region of a side wall of the component.

FIGS. 3 and 4 show a schematic lateral sectional representation and a schematic plan view representation of a lighting device comprising a row of optoelectronic components arranged next to one another, the components having the structure shown in FIGS. 1 and 2.

FIG. 5 shows a schematic plan view representation of a further lighting device comprising a row of optoelectronic components arranged next to one another, the components having a structure comparable to FIGS. 1 and 2 with a conversion element arranged in the region of another side wall.

FIG. 6 shows a schematic plan view representation of a further light device comprising two rows of optoelectronic components arranged next to one another, the components comprising a conversion element arranged in the region of two side walls.

FIG. 7 shows a schematic plan view representation of a further lighting device comprising two rows of optoelectronic components arranged next to one another, the components comprising a conversion element arranged in the region of three side walls.

FIGS. 8 and 9 show a schematic lateral sectional representation and a schematic plan view representation of a further lighting device comprising a row of optoelectronic components arranged next to one another, the components comprising a carrier substrate with a trapezoidal cross-sectional shape.

FIGS. 10 and 11 shows a schematic lateral sectional representation and a schematic plan view representation of a further lighting device comprising a row of optoelectronic components arranged next to one another, the components comprising a conversion element with a trapezoidal cross-sectional shape.

FIG. 12 shows a schematic lateral sectional representation of a further light device having optoelectronic components arranged next to one another, the components having a conversion element with a trapezoidal cross-sectional shape protruding laterally at a front side.

FIG. 13 shows a schematic lateral sectional representation of a further lighting device having optoelectronic components arranged next to one another, the components having a trapezoidal cross-sectional shape.

### LIST OF REFERENCES

101, 102 component
103, 104 component
111 front side
112 rear side
114, 115 side wall
116, 117 side wall
120 semiconductor chip
130 conversion element
131 emission surface
134, 135 edge section
136 edge section
139 recess
140 carrier substrate
147 connection
150 reflective layer
151 region
170 carrier
177 connection
179 solder
180 reflection element
189 bonding wire
191, 192 lighting device
193, 194 lighting device
199 extent direction
201, 202 component
203, 204 component
211 front side
212 rear side
214, 215 side
216, 217 side
220 semiconductor chip
230 conversion element
231 emission surface
235, 236 conversion element
239 recess
240, 245 carrier substrate
247 connection
250 reflective layer
262, 263 cross-sectional width of rear side
270 carrier
277 connection
279 solder
289 bonding wire
291, 292 lighting device
293, 294 lighting device
299 extent direction
A-A section line
B-B section line

### DETAILED DESCRIPTION

We provide an optoelectronic component. The optoelectronic component may comprise a carrier substrate, a single optoelectronic semiconductor chip arranged on the carrier substrate, an emission surface that emits light radiation, which is part of a front side of the optoelectronic component, and a reflective layer adjacent to the emission surface at the front side of the optoelectronic component. The emission surface is arranged such that the emission surface forms a part of the edge of the front side of the optoelectronic component.

The optoelectronic component described above is in the form of a single-chip component in which only a single optoelectronic semiconductor chip is arranged on the carrier substrate. In this way, a high flexibility for formation of a lighting device from a plurality of such optoelectronic components can be provided. The optoelectronic components may be arranged next to one another such that neighboring front-side emission surfaces of the optoelectronic components have a small or minimal spacing from one another.

This advantage is made possible by the edge-side structure described above, according to which the front-side emission surface of the optoelectronic component forms a part of the edge of the front side of the optoelectronic component. This may be the case in one or more regions so that the emission surface is arranged at at least one edge region of the front side. Compared to a conventional component, in which the front-side emission surface is fully enclosed by a reflective layer, space for the reflective material can be saved by the edge-side arrangement so that closer positioning of emission surfaces is possible. In an arrangement or alignment of a plurality of optoelectronic components, the spacing between two emission surfaces can be reduced in particular at least by the amount saved.

During operation of the optoelectronic component, light radiation can be emitted substantially through the emission surface. In addition to the front-side radiation, lateral emission of light radiation may take place in a region in which the emission surface forms a part of the edge of the front side. Efficiency losses due to the lateral light emission can be avoided or restricted by suitable configurations (for example, use of the reflectivity of a neighboring component). In another region, the reflective layer used for the radiation reflection, or a section, present at the front side, of the reflective layer, may adjoin the emission surface so that lateral emission of light radiation can be suppressed in such a region. The front-side section, adjacent to the emission surface, of the reflective layer may, in addition to the emission surface, form a further part of the front side of the optoelectronic component.

Further examples of the optoelectronic component with the emission surface arranged at the edge side will be described below. In particular, the optoelectronic semiconductor chip may be a light-emitting diode chip. A configuration in the form of a thin-film chip, i.e., a semiconductor chip emitting substantially through a front-side surface may, for example, be envisioned.

The front side of the optoelectronic component may be planar, or flat-surfaced.

The optoelectronic component may comprise a conversion element for radiation conversion arranged on the semiconductor chip. The conversion element comprises the front-side emission surface provided for emission of the light radiation. During operation of the optoelectronic component, the semiconductor chip may generate primary light radiation. The conversion element may convert at least a part of the primary radiation into conversion radiation. It is thus possible to generate from these radiation components mixed radiation which can be emitted by the conversion element. It is also possible for the conversion element to convert substantially all of the primary radiation of the semiconductor chip into the conversion radiation, and emit this.

The conversion element may be configured in the shape of a platelet. The conversion element may be arranged on a front side, or light exit side, of the optoelectronic semiconductor chip so that surface conversion (chip level conversion) is made possible. The conversion element may be fastened on the semiconductor chip with the aid of a transparent adhesive.

The edge-side arrangement of the emission surface may be achieved by the conversion element being arranged at at least one side wall, extending from the front side to an opposite rear side, of the optoelectronic component so that an edge section of the conversion element forms a part of the relevant side wall of the optoelectronic component. In this configuration, a conventional conversion element with a rectangular cross-sectional shape may be used. Emission of light radiation may take place substantially through the front-side emission surface of the conversion element. The lateral light emission described above may take place through the (at least one) edge section which is present at the side wall and is therefore exposed. The optoelectronic component may, for example, be configured such that the conversion element comprises one, or even two or three exposed edge sections. The rest of the edge of the conversion element, or one or more further edge sections of the conversion element, may be enclosed by the reflective layer so that the emerging light radiation can be reflected back again into the conversion element at these covered positions.

The conversion element, or the emission surface provided by the conversion element, may have substantially the same lateral dimensions as or even larger lateral dimensions than the semiconductor chip, or its light exit side. It is possible not only that the conversion element is arranged on the semiconductor chip, but also that the semiconductor chip is arranged in the region of at least one side wall of the optoelectronic component. In this way, an edge section of the semiconductor chip may also form a part of the relevant side wall. The remaining part, or edge, of the semiconductor chip may be enclosed by the reflective layer.

The conversion element arranged on the light exit side of the semiconductor chip may comprise a conversion material that induces the radiation conversion. It is possible for the conversion element to be a ceramic conversion element. As an alternative, a different conversion element may be used. One example is a conversion element consisting of a glass material or of a polymer material, or silicone, in which there is a conversion material in the form of embedded luminescent particles.

The optoelectronic component may be a white light source. To this end, the semiconductor chip may be configured to generate primary radiation in the blue to ultraviolet spectral range and the conversion element (or its conversion material) may be configured to generate conversion radiation in the yellow spectral range. White light radiation may be produced by superimposing these light radiations. It is also possible for the conversion element to comprise different conversion materials that generate conversion radiation composed of different radiation components. One example is one radiation component in the yellow to green spectral range and another radiation component in the red spectral range, which may likewise be superimposed with blue-violet primary radiation to form white light radiation. Besides white light radiation, the optoelectronic component may also be configured to generate light radiations of a different color, for example, yellow light radiation.

The reflective layer used for the radiation reflection may comprise an encapsulation material filled with reflective particles. The reflective layer may be arranged on the carrier substrate and may partially enclose the semiconductor chip and the conversion element.

The carrier substrate of the optoelectronic component, which may be configured with suitable connection or contact structures, may be a ceramic carrier substrate. A side of the carrier substrate facing away from the semiconductor chip may form the rear side of the optoelectronic component. At the rear side, the carrier substrate may have electrical connections with which the optoelectronic component can be mounted on a carrier of a lighting device. For example, an SMT mounting (surface mounted technology) method may be envisioned. In this case, a plurality of optoelectronic components may be arranged next to one another on the carrier while taking conventional fitting tolerances into account. As a result of the edge-side arrangement of the emission surfaces in the individual optoelectronic components, the emission surfaces can be positioned relatively close to one another.

The optoelectronic component may comprise a plurality of side walls extending from the front side to an opposite rear side. In this case, the emission surface is arranged at at least one side wall. The arrangement of the emission surface at more than one side wall may, in the case of alignment of a plurality of components configured in this way, favor close placement of emission surfaces.

The plurality of side walls extending from the front side to the rear side of the optoelectronic component may, for example, be planar.

The optoelectronic component may, for example, be cuboid and have a rectangular shape in plan view. There may therefore be four adjacent side walls between the front and rear side. The four side walls may respectively meet one another at a right angle. In relation to arrangement at more than one side wall, provision may, for example, be made for the emission surface to be arranged at two side walls. The two side walls may, for example, be side walls present at opposite sides of the optoelectronic component. It is, however, also possible for them to be mutually adjacent side walls. In another possible configuration, the emission surface may be arranged at three side walls of the optoelectronic component.

The semiconductor chip may have a rectangular shape in plan view. The conversion element may likewise have a rectangular shape, or substantially a rectangular shape, in plan view. The conversion element may have a recess at the edge or at a corner. In one possible configuration of the semiconductor chip with a front-side contact on the light exit side, contacting of the front-side contact may be made possible by the recess.

A lighting device is furthermore provided which comprises a carrier and a group of a plurality of optoelectronic components. The optoelectronic components are configured in the manner described above with an emission surface arranged at the edge side, or according to one of the examples described above. The optoelectronic components of the group are arranged in a row next to one another on the carrier. Because of the presence of the emission surfaces at the edge side in the individual optoelectronic components, the emission surfaces can be positioned close to, or at a minimal distance from, one another. In this way, the light pattern of the lighting device can be distinguished by minimal interference due to nonluminous regions.

In the lighting device, the optoelectronic components may have a matching alignment. The lighting device may, for example, constitute a vehicle headlamp or a part of a vehicle headlamp. The carrier on which the optoelectronic components are arranged may, for example, be a circuit board.

In the lighting device, the optoelectronic components of the group may respectively comprise a conversion element which is arranged at the edge side. Efficiency losses due to the lateral light emission at an exposed edge section of a conversion element can be avoided or restricted with the aid of the following configurations.

An edge section of a conversion element of an optoelectronic component of the group may be opposite to a reflective layer of a neighboring optoelectronic component of the group. The effect achievable in this way is that at least a part of light radiation emitted laterally through the edge section of the conversion element is reflected at the reflective layer lying opposite, and can therefore reach the edge section again and enter the conversion element. Efficiency losses are avoided or restricted as a result of the back-reflection. Furthermore, it is possible to suppress the occurrence of scattered light and crosstalk between neighboring components (which are optionally also operated separately from one another). This configuration may be provided in the region of all side walls, facing toward one another, of neighboring components of the group.

Edge sections of conversion elements of two neighboring optoelectronic components of the group may be opposite to one another. In this way, it is possible to achieve the effect that at least a part of the light radiation emitted laterally by an edge section of a conversion element can respectively reach the opposite edge section of the neighboring conversion element and enter the neighboring conversion element. In this way, efficiency losses can likewise be avoided or restricted. This configuration may also be provided in the region of all side walls, facing toward one another, of neighboring components of the group.

The lighting device may comprise two groups of optoelectronic components respectively arranged in a row next to one another on the carrier. In this case, edge sections of conversion elements of two neighboring optoelectronic components of the two groups are opposite to one another. In this way, it is correspondingly possible for at least a part of the light radiation emitted laterally at an edge section of the conversion element respectively to reach the opposite edge section of the neighboring conversion element and enter the neighboring conversion element. Efficiency losses can also be avoided or restricted in this way. This configuration may be provided in the region of all side walls, facing toward one another, of neighboring components of the two different groups.

The lighting device may comprise a reflective component having a reflective layer arranged on the carrier such that the reflective layer of the reflective component is opposite to an edge section of a conversion element of an optoelectronic component. In this way, it is possible to achieve the effect that at least a part of light radiation emitted laterally through the edge section of the conversion element is reflected at a reflective layer lying opposite, and can therefore reach the edge section again and enter the conversion element. The reflective component may, for example, be arranged in the region of the end of a row of optoelectronic components. The reflective component may, in a manner comparable to an optoelectronic component, comprise a carrier substrate on which only the reflective layer is arranged (dummy component).

The lighting device may comprise an additional reflective layer arranged on the carrier at least in intermediate regions between the optoelectronic components. The additional reflective layer may comprise the same material as, or a material comparable to, the reflective layer of the individual optoelectronic components, i.e., an encapsulation material filled with reflective particles. By the additional reflective layer, which may extend as far as the front sides of the optoelectronic components, and which may be present not only between the optoelectronic components but also in a region enclosing the optoelectronic components, (otherwise) exposed edge sections of conversion elements of the individual optoelectronic components can be covered. In this way, light radiation emerging at these positions can be reflected back again into the conversion element so that light emission can take place only through the front-side emission surfaces of the conversion elements.

The additional reflective layer may, for example, be used to separate opposite edge sections of conversion elements respectively of two neighboring optoelectronic components. In this way, it is possible to avoid crosstalk between the neighboring optoelectronic components. A configuration of the lighting device with the additional reflective layer may be implemented by intermediate regions between the components and a region enclosing the components being filled with a particle-filled encapsulation material to form the reflective layer after the mounting of the optoelectronic components on the carrier of the lighting device. The use of the additional reflective layer may, for example, be envisioned for a lighting device having optoelectronic components in which the associated conversion elements have two or three exposed edge sections.

A further optoelectronic component may be provided. The optoelectronic component comprises a carrier substrate, a single optoelectronic semiconductor chip arranged on the carrier substrate, an emission surface that emits light radiation, which is part of a front side of the optoelectronic component, and a reflective layer adjacent to the emission surface at the front side of the optoelectronic component. The emission surface has a cross-sectional width at least as large as a cross-sectional width of a rear side, opposite the front side of the optoelectronic component.

The optoelectronic component described above is in the form of a single-chip component in which only a single optoelectronic semiconductor chip is arranged on the carrier substrate. In this way, a high flexibility can be provided for formation of a lighting device from a plurality of such optoelectronic components. The optoelectronic components may be arranged next to one another such that neighboring front-side emission surfaces of the optoelectronic components have a small or minimal spacing from one another.

This advantage is also made possible by the structure described above, according to which the width of the emission surface of the conversion element in a cross section of the optoelectronic component is at least as large as the width of the rear side of the optoelectronic component. In this way, the spacing between two emission surfaces in an arrangement or alignment of a plurality of optoelectronic components can be equally large as or less than the spacing between rear sides of the associated components.

In a conventional single-chip component, the presence of an emission surface enclosed by a reflective layer at the front side usually has the effect that the emission surface has a smaller cross-sectional width compared to a rear side. In an alignment of conventional components, the emission surfaces therefore have larger spacings than the rear sides. The proposed width configuration differing therefrom consequently makes it possible to reduce or minimize existing spacings.

The cross section in which the emission surface is at least as wide as the rear side relates to a direction dictated by a lateral extent, or transverse extent, of the optoelectronic component. A lighting device comprising a plurality of optoelectronic components may have minimal spacings between the emission surfaces by the components being arranged next to one another with a matching orientation along this extent direction.

Further possible examples of the optoelectronic component with the advantageous width feature will be described below. The optoelectronic semiconductor chip may, in particular, be a light-emitting diode chip. A configuration in the form of a thin-film chip, i.e., a semiconductor chip emitting substantially through a front-side surface may, for example, be envisioned.

The front side of the optoelectronic component may be planar, or flat-surfaced.

The optoelectronic component may comprise a conversion element for radiation conversion arranged on the semiconductor chip. The conversion element comprises the front-side emission surface provided for emission of light radiation. During operation of the optoelectronic component, the semiconductor chip may generate primary light radiation. The conversion element may convert at least a part of the primary radiation into conversion radiation. In this way, from these radiation components, it is possible to generate mixed radiation which can be emitted by the conversion element. It is also possible for the conversion element to convert substantially all of the primary radiation of the semiconductor chip into the conversion radiation, and emit this.

The conversion element may be configured in the shape of a platelet. The conversion element may be arranged on a front side, or light exit side, of the optoelectronic semiconductor chip so that surface conversion is made possible. The conversion element may be fastened on the semiconductor chip with the aid of a transparent adhesive. The conversion element or the emission surface provided by the conversion element may optionally substantially have the same lateral dimensions as or even larger lateral dimensions than the semiconductor chip, or its light exit side.

The conversion element may comprise a conversion material that induces the radiation conversion. It is possible for the conversion element to be a ceramic conversion element. As an alternative, a different conversion element may be used. One example is a conversion element consisting of a glass material or of a polymer material, or silicone, in which there is a conversion material in the form of embedded luminescent particles.

The optoelectronic component may be a white light source. To this end, the semiconductor chip may be configured to generate primary radiation in the blue to ultraviolet spectral range and the conversion element (or its conversion material) may be configured to generate conversion radiation in the yellow spectral range. White light radiation may be produced by superimposing these light radiations. It is also possible for the conversion element to comprise different conversion materials that generate conversion radiation composed of different radiation components. One example is one radiation component in the yellow to green spectral range and another radiation component in the red spectral range, which may likewise be superimposed with blue-violet primary radiation to form white light radiation. The optoelectronic component may also be configured to generate light radiations of a different color, for example, yellow light radiation.

The reflective layer used for the radiation reflection may comprise an encapsulation material filled with reflective particles. The reflective layer may be arranged on the carrier substrate and partially enclose the semiconductor chip and the conversion element.

The semiconductor chip or its edge may be fully enclosed by the reflective layer. The conversion element arranged on the semiconductor chip may likewise be fully enclosed by the reflective layer at the edge. In this way, only the emission surface of the conversion element which may form a part of the front side of the optoelectronic component may be exposed. In this way, it is possible to achieve the effect that light radiation is emitted only through the emission surface of the conversion element during operation of the optoelectronic component. Nevertheless, examples in which (minor) lateral emission of light radiation can emerge in addition to the front-side radiation emission may also be envisioned.

The carrier substrate of the optoelectronic component, which may be configured with suitable connection or contact structures, may be a ceramic carrier substrate. A side of the carrier substrate facing away from the semiconductor chip may form the rear side of the optoelectronic component. At the rear side, the carrier substrate may have electrical connections with which the optoelectronic component can be mounted on a carrier of a lighting device. For example, an SMT mounting method may be envisioned. In this case, a plurality of optoelectronic components may be arranged next to one another on the carrier while taking conventional fitting tolerances into account. By the presence of emission surfaces which in cross section are at least as wide as the rear sides of the individual optoelectronic component, the emission surfaces can be positioned relatively close to one another.

The optoelectronic component may have a rectangular shape in plan view. The optoelectronic component may furthermore have two lateral extent directions extending perpendicularly to one another. In relation to one of the two extent directions, the emission surface may be at least as wide as the rear side of the optoelectronic component.

The semiconductor chip may have a rectangular shape in plan view. The conversion element may likewise have a rectangular shape, or substantially a rectangular shape, in plan view. The conversion element may have a recess at the edge or at a corner. In one possible configuration of the semiconductor chip with a front-side contact on the light exit side, contacting of the front-side contact may be made possible by the recess.

The conversion element may have a cross-sectional shape at least partially widening in the direction of the emission surface. This relates to that cross section of the optoelectronic component in which there is the above-described width feature of the component. A plurality of optoelectronic components having such a structure may be positioned next to one another with a small spacing of the front-side emission surfaces. The conversion element may, for example, have in cross section a simply producible trapezoidal shape with sides extending obliquely with respect to the emission surface. Furthermore, the component may be configured such that the front-side emission surface of the widening or trapezoidal conversion element reaches to the edge of the component at two opposite sides.

A relatively small spacing of the emission surfaces is possible, in particular, in such a configuration in which the conversion element with the at least partially widening cross-sectional shape laterally protrudes, or overhangs, in the region of the front side of the optoelectronic component. In this way, the conversion element may also be partially exposed at the edge side. Lateral emission of light radiation can therefore take place in this configuration.

When there is lateral light emission, efficiency losses may optionally be avoided or at least restricted with the aid of a neighboring optoelectronic component, the opposite conversion element of which can be at least partially entered by the laterally emitted light radiation, or with the aid of an opposite reflective layer at which the laterally emitted light radiation can be at least partially reflected back. The reflective layer allowing the back-reflection may be part of a neighboring optoelectronic component or of a neighboring reflective component.

The carrier substrate may have a cross-sectional shape at least partially widening in the direction of the front side of the optoelectronic component. This relates to that cross section of the optoelectronic component in which there is the width feature of the component. The carrier substrate may, for example, have in cross section a simply producible trapezoidal shape with sides extending obliquely with respect to the front and rear sides of the optoelectronic component. A plurality of optoelectronic components having such a structure can be positioned next to one another with a small spacing of the front-side emission surfaces. The rear sides or rear-side subregions of the optoelectronic components may, conversely, be spaced relatively far apart from one another.

The optoelectronic component may have a cross-sectional shape at least partially widening in the direction of the front side. This relates to that cross section of the optoelectronic component in which there is the width feature of the component. It is, for example, possible for the entire optoelectronic component to have in cross section a simply producible trapezoidal shape with side walls extending obliquely with respect to the front and rear sides. This configuration also allows arrangement or alignment of a plurality of optoelectronic components with a small spacing of the front-side emission surfaces. Other subregions, in particular rear-side subregions, of the optoelectronic components may, conversely, be spaced relatively far apart from one another.

In relation to the above-described configurations of the conversion element, of the carrier substrate and/or of the optoelectronic component with the widening cross-sectional shapes, it may be envisioned that there is widening only in one or more subregions of the conversion element, of the carrier substrate and/or of the optoelectronic component, while one or more other subregions have a constant cross-sectional width. Besides trapezoidal shapes, or obliquely extending contours and sides, other shapes are also possible, for example, curved contours. Furthermore, it is possible for there to be a plurality of subregions widening to a different extent in cross section, or differently obliquely extending side sections or side-wall sections.

A lighting device is furthermore provided which comprises a carrier and a group of a plurality of optoelectronic components. The optoelectronic components are configured in the manner described above with the width feature or according to one of the examples described above. The optoelectronic components of the group are arranged in a row next to one another on the carrier. In this case, in relation to an extent direction of the row, for each of the optoelectronic components of the row the cross-sectional width of the emission surface is at least as large as the cross-sectional width of the rear side. In other words, the optoelectronic components of the group have a matching alignment (along the extension direction). The emission surfaces can consequently be positioned with a small or minimal spacing from one another. In this way, the light pattern of the lighting device can be distinguished by minimal interference due to nonluminous regions.

The lighting device may, for example, constitute a vehicle headlamp or a part of a vehicle headlamp. The carrier on which the optoelectronic components are arranged may, for example, be a circuit board.

If, in the lighting device, optoelectronic components are used in which light emission takes place not only through the emission surfaces but in addition also laterally, efficiency losses may be reduced according to the approaches presented above. For example, light radiation emitted laterally by a conversion element of an optoelectronic component may be coupled at least partially into a conversion element of a neighboring optoelectronic component. It is also possible for laterally emitted light radiation to be reflected back at least partially at a reflective layer lying opposite. The reflective layer may be comprised of a neighboring reflective component, which may be provided in the lighting device on the carrier. The lighting device may furthermore comprise an additional reflective layer arranged on the carrier, at least in intermediate regions between the optoelectronic components.

In relation to the optoelectronic component described above and its possible examples, reference is made to the possibility of optionally implementing such a component independently of the width feature described above. An optoelectronic component configured in this respect may comprise the following: a carrier substrate, a single optoelectronic semiconductor chip arranged on the carrier substrate, an emission surface that emits light radiation, which is part of a front side of the optoelectronic component, and a reflective layer adjacent to the emission surface at the front side of the optoelectronic component. Provision may furthermore be made that the optoelectronic component has a cross-sectional shape widening at least partially, that the carrier substrate has a cross-sectional shape widening at least partially, and/or that the optoelectronic component has a conversion element, arranged on the semiconductor chip, which provides the emission surface with a cross-sectional shape widening at least partially. In such configurations, the width configuration (the cross-sectional width of an emission surface is at least as large as a rear-side cross-sectional width) may or may not be implemented. The examples mentioned above may be applied in the same way in such an optoelectronic component. In particular, the above-described trapezoidal shapes existing in cross section may be provided. In a plurality of optoelectronic components having such a structure, close positioning of the emission surfaces may be made possible. An associated lighting device may as well comprise a carrier and a group of a plurality of such optoelectronic components, the optoelectronic components of the group being arranged in a row next to one another on the carrier. The at least partially widening cross-sectional shapes relate to an extent direction of the row.

The advantageous configurations and refinements explained above may, except, for example, in unique dependencies or incompatible alternatives, be applied individually or in any combination with one another.

The above-described properties, features and advantages, as well as the way in which they are achieved, will become more clearly and comprehensively understandable in connection with the following description of examples which will be explained in more detail in connection with the schematic drawings.

Examples of optoelectronic single-chip components (also referred to as single emitters) and examples of lighting devices having a plurality of such optoelectronic components will be described on the basis of the following schematic figures. The optoelectronic components comprise a single optoelectronic semiconductor chip, a carrier substrate, a conversion element and a reflective layer. The use of the single-chip components offers the possibility of flexibly implementing different examples of lighting devices, in particular with different numbers of components. The single-chip components are configured such that front-side planar luminous or emission surfaces can be positioned relatively close to one another. In this way, it is possible to provide a light pattern with an improved homogeneity.

The optoelectronic components shown and described may be produced with the aid of processes known from semiconductor technology and from the fabrication of optoelectronic components, and they may comprise conventional materials so that this will only be partially discussed. Furthermore, besides structures shown and described, the components may comprise further parts, structures and/or layers. The figures are schematic in nature and sometimes not true to scale. Parts and structures shown in the figures may therefore be represented exaggeratedly large or with a reduced size for better understanding.

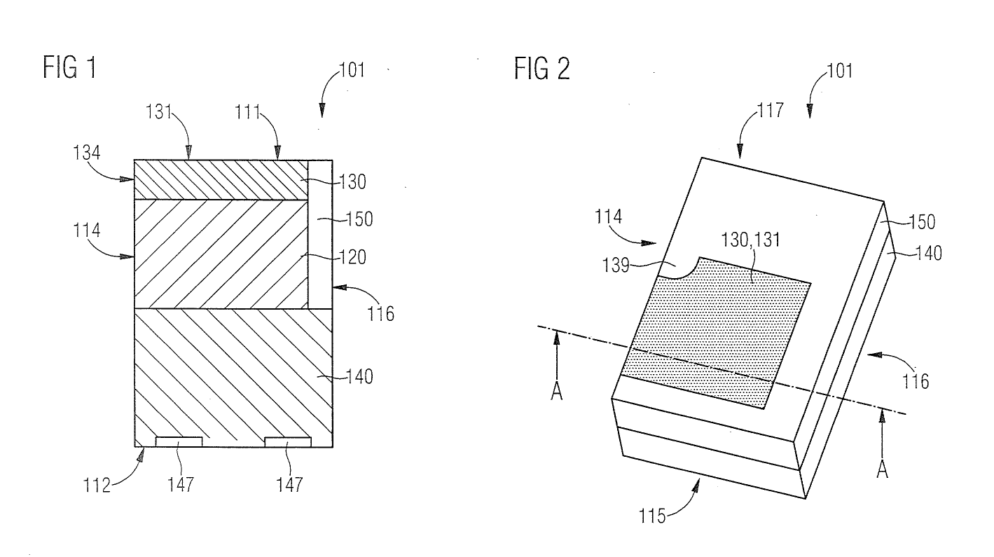

A concept to allow small spacings of emission surfaces 131 of optoelectronic components arranged next to one another will be described on the basis of FIGS. 1 to 7. This is based on positioning a front-side emission surface 131 such that in one or more regions the emission surface 131 forms a part of the edge of a flat-surfaced front side of an optoelectronic component. To this end, the optoelectronic component is configured such that a conversion element 130 providing the emission surface 131 is arranged in the region of at least one side wall of the component.

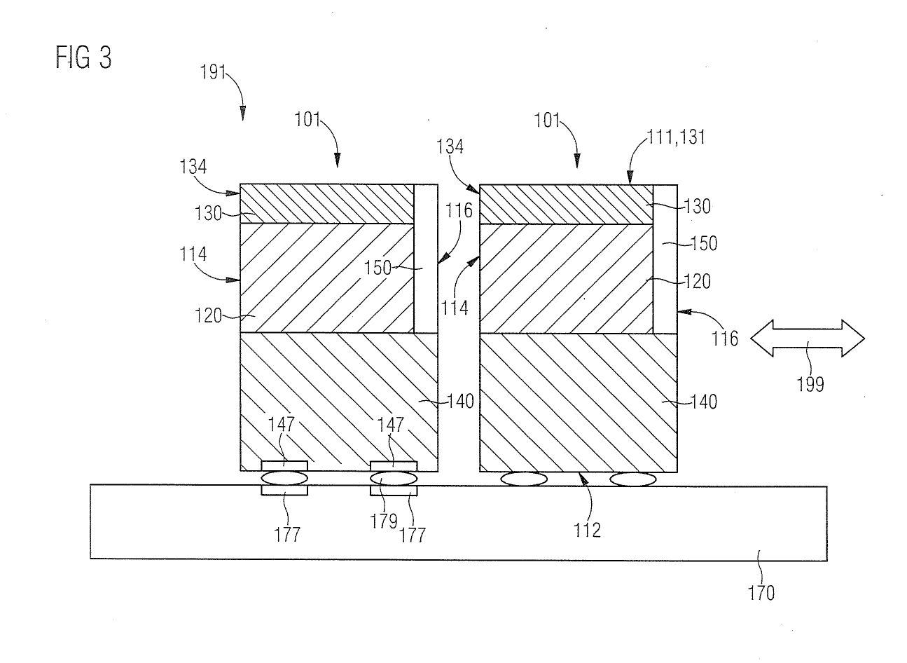

FIGS. 1 and 2 show an example of an optoelectronic component 101 configured in a lateral sectional representation and in a perspective representation. The sectional representation of FIG. 1 refers to the section plane indicated with the aid of the section line A-A in FIG. 2.

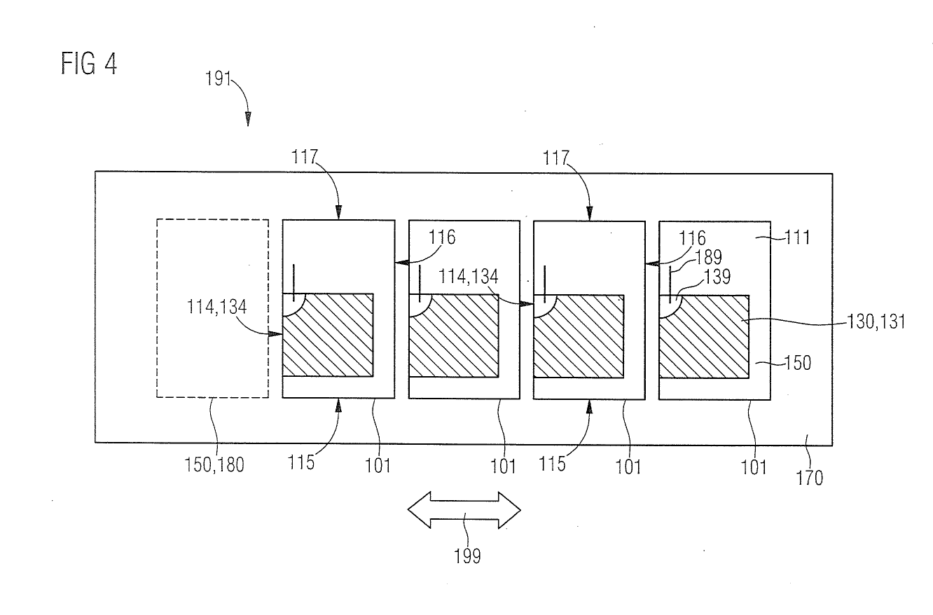

The optoelectronic component 101 is configured in the shape of a cuboid, and has in plan view a rectangular shape with differently long sides, i.e., two parallel first longer sides and two parallel second shorter sides (cf. FIG. 4). The component 101 has two end sides 111, 112 lying opposite, referred to below as the front side 111 and the rear side 112, and four side walls 114, 115, 116, 117 present at the edge. The side walls 114, 115, 116, 117, which extend between the front and rear sides 111, 112, respectively meet at a right angle. In this case, the side walls 114, 116 constitute the aforementioned first sides, or long sides, and the side walls 115, 117 constitute the second sides, or short sides. The side walls 114, 115, 116, 117 may be planar.

The optoelectronic component 101 comprises, as shown in FIG. 1, a carrier substrate 140 used as a base, a single optoelectronic semiconductor chip 120 for radiation generation, arranged on the carrier substrate 140, a platelet-shaped conversion element 130 for radiation conversion, or surface conversion, arranged on the semiconductor chip 120, and a reflective layer 150 arranged on the carrier substrate 140. The reflective layer 150 used for radiation reflection adjoins the semiconductor chip 120 and the conversion element 130. The semiconductor chip 120 and the conversion element 130 are, apart from subregions in the region of the side wall 114, in particular laterally enclosed at the edge, or circumferentially, by the reflective layer.

The optoelectronic semiconductor chip 120 may in particular be a light-emitting diode chip, or LED chip. For example, a configuration in the form of a thin-film chip may be envisioned. To this end, the semiconductor chip 120 is configured to generate primary light radiation during operation with electrical energy being supplied. The primary radiation may be substantially emitted through a front side of the semiconductor chip 120, which is also referred to as the light exit side or light exit surface of the semiconductor chip 120. The conversion element 130 is arranged directly on this side of the semiconductor chip 120. The semiconductor chip 120, or its light exit side, has a rectangular shape in plan view.

To supply electrical energy to the optoelectronic semiconductor chip 120, the semiconductor chip 120 is configured with two electrical contacts. In the example described here, the semiconductor chip 120 has a front-side contact in the region of the light exit side, and a rear-side contact at a rear side (not represented), opposite to the light exit side, of the semiconductor chip 120.

The carrier substrate 140 used to carry the semiconductor chip 120 comprises, on a front side on which the semiconductor chip 120 and the reflective layer 150 are arranged, a mating contact (not shown) matched to the rear-side contact of the semiconductor chip 120. The rear-side contact of the semiconductor chip 120 and the mating contact of the carrier substrate 140 may be electrically connected to one another by a solder (not represented). In this way, the semiconductor chip 120 can simultaneously be mechanically fastened on the carrier substrate 140. For the front-side contact of the semiconductor chip 120 arranged at the edge or at a corner of the semiconductor chip 120, the carrier substrate 140 comprises a further mating contact (not represented) arranged on its front side. An electrical connection between this mating contact and the front-side contact of the semiconductor chip 120 is established by a bonding wire 189 (cf. FIG. 4). The bonding wire 189 is embedded in the reflective layer 150.

The carrier substrate 140 configured as a cuboid may, for example, be a ceramic carrier substrate. A rear side, opposite to the front side of the carrier substrate 140, forms the rear side 112 of the optoelectronic component 101. At this side 112, as shown in FIG. 1, the carrier substrate 140 has two electrical connections 147 so that electrical energy can be supplied to the component 101 and, therefore, to the semiconductor chip 120. The connections 147, provided, for example, in the form of solder surfaces may, for example, have a strip shape and extend parallel to the long sides 114, 116 of the component 101. The connections 147 electrically connect (not shown) by suitable connection structures, extend vertically through the carrier substrate 140, to mating contacts present at the front side of the carrier substrate 140.

The platelet-shaped conversion element 130 arranged on the light exit side of the optoelectronic semiconductor chip 120 may, for example, be fastened (not represented) on the semiconductor chip 120 with the aid of a transparent adhesive, for example, a silicone adhesive. The conversion element 130 is configured to convert at least a part of the primary radiation generated by the semiconductor chip 120 during operation into lower-energy conversion radiation. The primary radiation can emerge at the light exit side of the semiconductor chip 120 and therefore be coupled into the conversion element 130.

For the radiation conversion, the conversion element 130 comprises a suitable conversion material which can absorb the primary radiation and be excited to re-emit the conversion radiation. In this way, it is possible to generate mixed radiation comprising the primary radiation and the conversion radiation which can be emitted by the conversion element 130. It is also possible for the conversion element 130 to convert substantially all of the primary radiation of the semiconductor chip 120 into the conversion radiation and emit the latter. The conversion element 130 may, for example, be a ceramic conversion element 130.

The conversion element 130, which may have the same or substantially the same lateral dimensions as the semiconductor chip 120, or as its light exit side, is positioned congruently over the light exit side of the semiconductor chip 120. The conversion element 130 may also have larger lateral dimensions. The conversion element 130 has a substantially rectangular shape in plan view, comparable to the semiconductor chip 120. With a view to the front-side contact of the semiconductor chip 120, the conversion element 130, as shown in FIG. 2, is configured with a recess 139 adapted thereto in the region of a corner. In this way, the front-side contact can be exposed and contacted by a bonding wire 189 (cf. FIG. 4). In the cross section shown in FIG. 1, the conversion element 130 has a rectangular shape. In a section plane extending parallel thereto (parallel to the sides 114, 116), the conversion element 130 likewise has a rectangular shape (not represented).

The optoelectronic component 101 may, for example, be a white light source. This may be achieved by the semiconductor chip 120 being configured to generate primary radiation in the blue to ultraviolet spectral range, and the conversion element 130 being configured to generate conversion radiation in the yellow spectral range. The blue-violet light radiation and the yellow light radiation may be superimposed to form white light radiation (additive color mixing). Other configurations are, however, also possible. For example, the conversion element 130 may comprise different conversion materials so that conversion radiation generated by the conversion element 130 may comprise a plurality of radiation components of different spectral ranges. In relation to blue-violet primary radiation, the conversion element 130 may, for example, be configured to emit a first radiation component in the yellow to green spectral range and a second radiation component in the red spectral range. These radiation components may, together with the blue-violet primary radiation, likewise lead to white light radiation. As an alternative, the optoelectronic component 101 may also be configured to emit light radiation with a different color, for example, yellow light radiation instead of white light radiation.

During operation of the optoelectronic component 101, its light radiation is emitted through the conversion element 130. Emission of the light radiation takes place substantially through an extensive front side 131 of the platelet-like conversion element 130, which will be referred to below as the luminous surface or emission surface 131. The emission surface 131 is located at the front side 111 of the optoelectronic component 101 and is a part of the front side 111.

The reflective layer 150 arranged on the carrier substrate 140 and partially enclosing or embedding the semiconductor chip 120 and the conversion element 130 is made of a matrix material or encapsulation material, for example, silicone with reflective particles, for example, consisting of titanium oxide, contained therein. The reflective layer 150 extends as far as the front side 111 of the component 101 and therefore forms, with a front-side section, in addition to the emission surface 131, a further (remaining) part of the front side 111. The front-side section, adjacent to the emission surface 131, of the reflective layer 150 is substantially U-shaped (cf. FIGS. 2 and 4). The reflective layer 150 ensures that, in the optoelectronic component 101, emission of light radiation substantially takes place through the emission surface 131 of the conversion element 130.

In the optoelectronic component 101, the conversion element 130 is arranged in the region of the side wall 114. Owing to this asymmetric placement, the front-side emission surface 131 is also positioned at the edge of the component 101 and therefore forms a part of the edge of the front side 111. The effect of the edge-side arrangement is that an edge section 134, extending perpendicularly to the emission surface 131, of the conversion element 130 forms a part of the relevant side wall 114 (cf. FIG. 1). In addition to the front-side radiation emission through the emission surface 131, lateral emission of light radiation may take place through the exposed edge section 134. The rest of the edge region or further edge sections of the conversion element 130 are, conversely, enclosed by the reflective layer 150 so that light radiation emerging at these positions can be reflected back into the conversion element 130.

The semiconductor chip 120 on which the conversion element 130 is arranged congruently is also arranged asymmetrically and located in the region of the side wall 114 so that an edge section of the semiconductor chip 120 can form a part of the side wall 114. The remaining part or edge of the semiconductor chip 120 is enclosed by the reflective layer 150.

In a production method, a plurality of optoelectronic components 101 may be fabricated together, or in parallel. In this case, a continuous carrier substrate 140, on which a plurality of semiconductor chips 120 and conversion elements 130 thereon is arranged, may be provided for a plurality of components 101. After connection of bonding wires 189 to front-side contacts of the chips 120 and mating contacts of the continuous carrier substrate 140, regions between the semiconductor chips 120 and conversion elements 130 and around these, may be filled with a particle-filled encapsulation material to form the reflective layer 150. At the end of the production method, a separation process may be carried out to provide separate optoelectronic components 101.

Configuration of the optoelectronic component 101 with the conversion element 130 placed at the edge side or asymmetrically offers the possibility of implementing a lighting device with a plurality of such components 101 such that neighboring conversion elements 130 and, therefore, front-side emission surfaces 131 have a small spacing from one another. The components 101 may be arranged on the carrier according to a spacing grid or mounting grid, which is dictated by a carrier of the lighting device.

In a conventional single-chip component with a reflective layer, in contrast to the optoelectronic component 101, the associated conversion element and, therefore, its front-side emission surface is fully enclosed by the reflective layer. In an arrangement of a plurality of components, this leads to relatively large spacings between the emission surfaces. The edge-side configuration of the component 101, in comparison with this, offers the possibility of saving on space for reflective material and a housing wall thereby formed. This makes it possible in an alignment of a plurality of components 101 to reduce the spacing of the conversion element 130 at least by the amount saved. The conversion elements 130 can therefore be arranged closer to respectively neighboring conversion elements 130. The smaller spacings allow a more uniform luminous surface formed by the emission surfaces 131 of the conversion elements 130.

In the optoelectronic component 101, in contrast to a conventional component, although lateral emission of light radiation takes place through the exposed edge section 134, present at the side wall 114 of the conversion element 130 an associated loss can, however, be suppressed by a suitable configuration of the lighting device, as will be explained in more detail below.

To illustrate this aspect, FIGS. 3 and 4 show an example of a lighting device 191 in a lateral sectional representation and in a plan view representation. The lighting device 191 comprises a group of a plurality of optoelectronic components 101 arranged next to one another. Two of the four components 101 shown in FIG. 4 are represented in FIG. 3. It is possible for the lighting device 191 to have a different, in particular larger, number of components 101 arranged next to one another. The lighting device 191 may, for example, be part of a vehicle headlamp.

The lighting device 191 comprises, in addition to the optoelectronic components 101, a relatively large carrier 170. The components 101 of the group are arranged linearly or in the form of a row next to one another on the carrier 170. Such a configuration may also be referred to as a one-dimensional or 1D arrangement. An arrangement or extent direction 199 of the row is indicated with the aid of a double arrow in FIGS. 3 and 4.

The carrier 170 may, for example, be a circuit board. The carrier 170 comprises electrical connections 177 adapted to the rear-side electrical connections 147 of the components 101 to supply the optoelectronic components 101 with electrical energy. The connections 147, 177 may be connected to one another by a solder 179. This is represented in FIG. 3 only in relation to the left-hand component 101. The components 101 may, for example, be arranged on the carrier 170 by an SMT mounting (surface mounted technology) method, with a reflow solder process being used. The connections 177, provided for the components 101 of the carrier 170 may be present in a predetermined spacing grid, the spacings of the components 101 on the carrier being predetermined thereby.

The optoelectronic components 101 arranged on the carrier 170 respectively have the same lateral alignment and are oriented with the side walls, or short sides, 115, 117 along the extent direction 199. In this way, the conversion elements 130 and, therefore, the front-side emission surfaces 131 of the individual components 101 can have a small spacing from one another. For respectively two neighboring components 101, the side walls, or long sides, 114, 116, face toward one another. Owing to the mutually opposing side walls 114, 116, an edge section 134 of a conversion element 130 of one component 101 respectively is opposite to a reflective layer 150 of a neighboring component 101. In this way, it is respectively possible to achieve the effect that light radiation emerging laterally through an edge section 134 of a conversion element 130 is at least partly reflected at the reflective layer 150 lying opposite, and can reach the edge section 134 again and enter into the associated conversion element 130. By this configuration, efficiency losses during operation of the lighting device 191 can be avoided or at least restricted.

An optoelectronic component 101 present at the end of the row (on the left in FIG. 4) is not assigned a component 101 as a reflection partner. It is possible to neglect the loss due to the light radiation emerging laterally at this component 101. As an alternative, back-reflection may also be provided for the component 101 arranged at the row end. To this end, a reflective component 180 may additionally be arranged next to the component 101 as indicated in FIG. 4, on the carrier 170. The reflective component 180 may in a manner comparable to an optoelectronic component 101 comprise a carrier substrate 140 on which only the reflective layer 150 is arranged (dummy component). In this way, the edge section 134 of the conversion element 130 of the optoelectronic component 101 present at the row end can be opposite to the reflective layer 150 of the reflective component 180 and, consequently, at least partial reflection of the laterally emitted light radiation back to the edge section 134 can also be induced at this position. The reflective component 180 may also be arranged on the carrier 170 in the scope of SMT mounting.

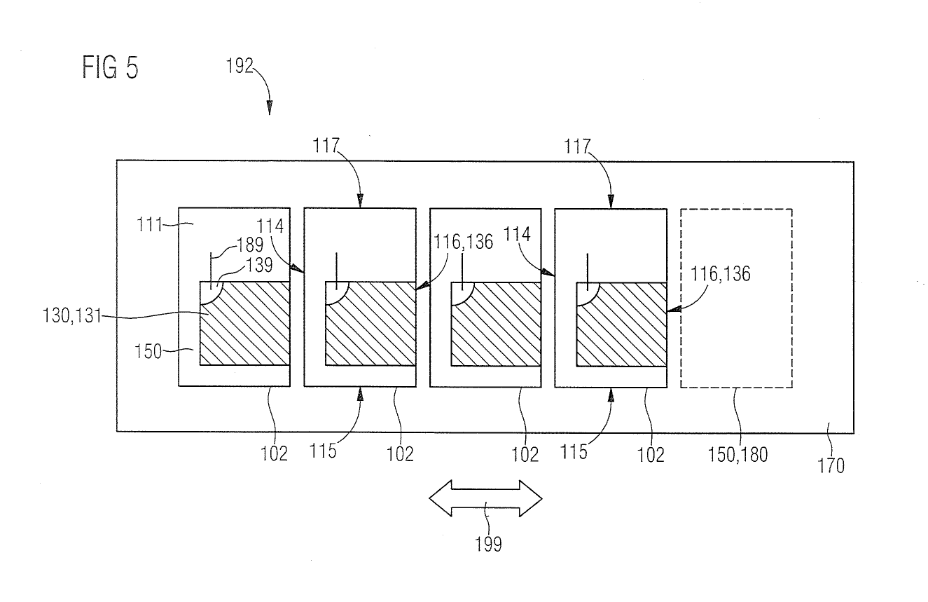

Further examples of optoelectronic components and associated lighting devices which represent refinements of the component 101 and of the lighting device 191 will be explained with the aid of the following FIGS. 5 to 7. The optoelectronic components comprise a carrier substrate 140, a semiconductor chip 120 arranged on the carrier substrate 140, a conversion element 130 arranged on the semiconductor chip 120, and a reflective layer 150 arranged next to the semiconductor chip 120 and the conversion element 130 on the carrier substrate 140. Parts which are the same and have the same effect will not be described again in detail below. For details regarding corresponding features, production, possible advantages and the like, reference is instead made to the description above. It is furthermore to be pointed out that details which have been mentioned in relation to one of the examples below may also apply to other examples.

FIG. 5 shows a plan view representation of a lighting device 192 having optoelectronic components 102 arranged in the form of a row next to one another on a carrier 170. The lighting device 192, or its components 102, correspond substantially to the lighting device 191 described above or its components 101. In contrast to the component 101, in a component 102 the conversion element 130 and the semiconductor chip 120 located underneath are arranged not in the region of the side wall 114 but in the region of the side wall 116 opposite to the latter. The asymmetrically placed conversion element 130 therefore has an exposed edge section 136 at the side wall 116, which forms a part of the side wall 116. Furthermore, the recess 139 of the conversion element 130 no longer adjoins the side wall 114, as in the case of the component 101.

In the lighting device 192, the optoelectronic components 102, in a manner comparable to the lighting device 191, have the same lateral alignment and are oriented with the side walls 115, 117 along the extent direction 199 of the row so that there can be a small spacing between the front-side emission surfaces 131 of the conversion elements 130. The side walls 114, 116 of respectively two neighboring components 102 face toward one another. At these positions, an edge section 136 of a conversion element 130 is therefore respectively opposite to a reflective layer 150. Light radiation emerging laterally at an edge section 136 can in this way respectively be reflected back again at least partially to the edge section 136 and therefore be coupled into the relevant conversion element 130. In relation to the components 102 located at the end of the row (on the right in FIG. 5), reflection back to the edge section 136 can be made possible by arranging at this position an optional reflective component 180 having a reflective layer 150.

An optoelectronic component may also, unlike the components 101, 102, be configured such that the conversion element 130 is arranged not only in the region of a side wall, but instead in the region of a plurality of side walls. This may, for example, be used in two-row arrangements of components to permit a small spacing of conversion elements 130 and therefore emission surfaces 131.

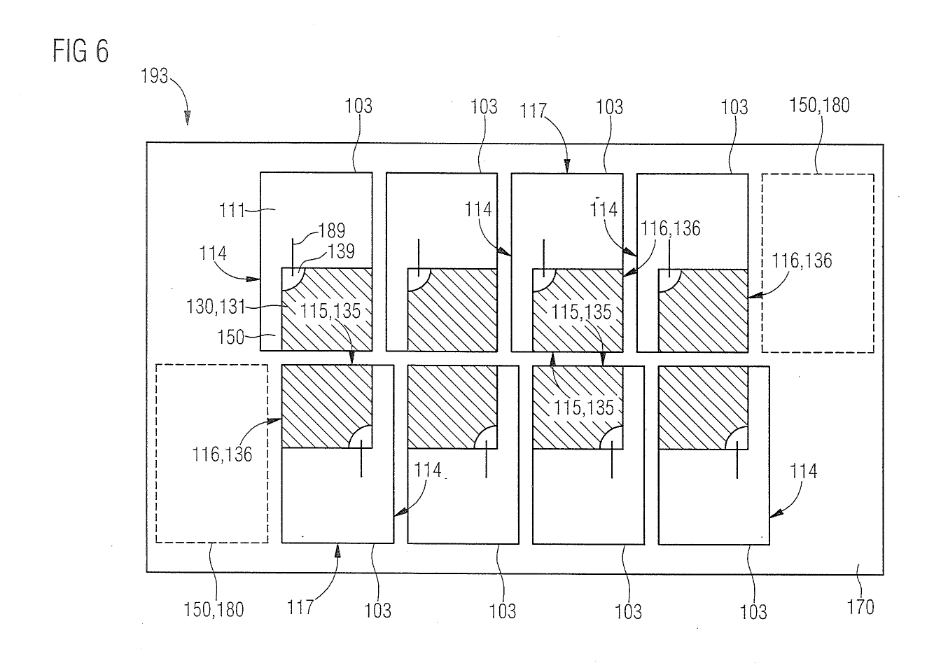

For illustration, FIG. 6 shows a plan view representation of a further lighting device 193 comprising two groups of a plurality of optoelectronic components 103 respectively arranged in a row next to one another on a carrier 170. Such a configuration may also be referred to as a two-dimensional arrangement, or 2D arrangement. Each row may, as shown in FIG. 6, comprise four components 103 or, alternatively, a different or greater number of components 103.

In an optoelectronic component 103, in contrast to the component 101, the conversion element 130 and the semiconductor chip 120 located underneath are arranged in the region of the two mutually adjoining side walls 115, 116. The asymmetrically placed conversion element 130 therefore has both an exposed edge section 135 at the side wall 115 and an exposed edge section 136 at the side wall 116. The two edge sections 135, 136, which meet at a right angle, respectively form a part of the side walls 115, 116. In this configuration, the front-side section, adjacent to the emission surface 131, of the reflective layer 150 has an L-shaped geometry. The emission surface 131 also forms a part of the edge of the front side 111 in the region of the two sides 115, 116.

In each of the two rows of the lighting device 193, the associated optoelectronic components 103 have the same lateral alignment and are oriented with the side walls 115, 117 along the extent direction of a row. In this way, the front-side emission surfaces 131 can have a small spacing from one another. The side walls 114, 116 of neighboring components 103 in each row face toward one another. The effect of this is that, for respectively two neighboring components 103 of a row, an edge section 136 of a conversion element 130 is opposite to a reflective layer 150. Light radiation emerging laterally at an edge section 136 can in this way respectively be reflected back at least partially to the edge section 136. In relation to the components 103 present at the end of the two rows, reflection back to the edge sections 136 can be made possible by arranging at these positions an optional reflective component 180 having a reflective layer 150, as indicated in FIG. 6.

In the lighting device 193, furthermore, the conversion elements 130 and therefore the emission surfaces 131 of the optoelectronic components 103 of the two different rows are also arranged with a small spacing from one another. To this end, the two rows of components 103 are oriented parallel or antiparallel with respect to one another. In this case, the side walls 115 and the edge sections 135, present here, of conversion elements 130 of neighboring components 103 of the different rows respectively are opposite to one another. In this way, it is respectively possible to achieve the effect that at least a part of the light radiation emitted laterally through an edge section 135 of a conversion element 130 can reach the opposite edge section 135 of the neighboring conversion element 130 and enter into the relevant conversion element 130. In this way, it is likewise possible to avoid or at least restrict efficiency losses.

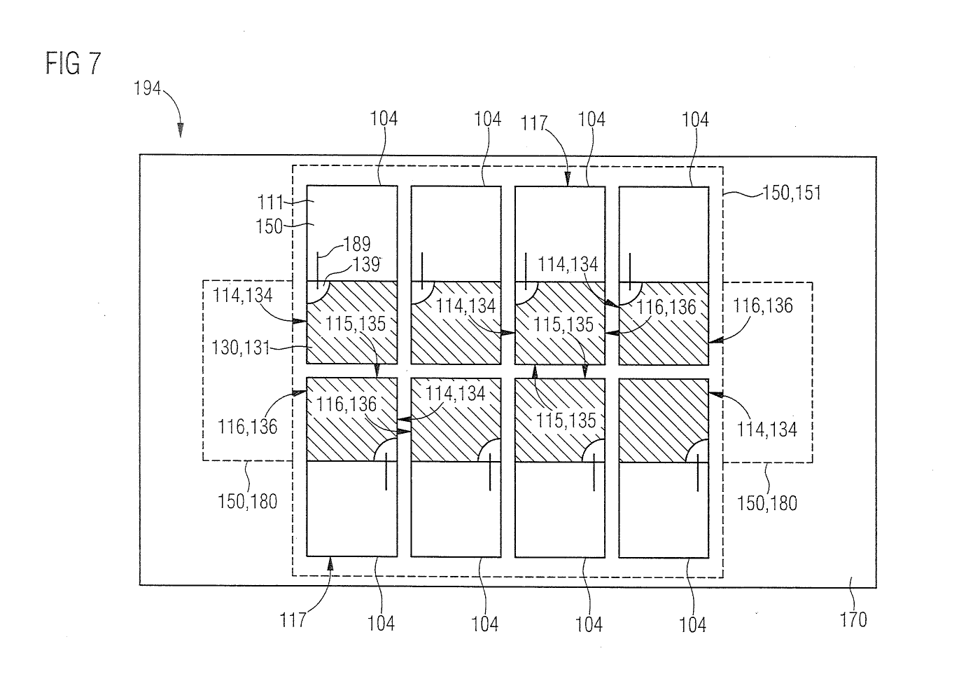

FIG. 7 shows a plan view representation of a further lighting device 194 comprising two groups of a plurality of optoelectronic components 104 respectively arranged in a row next to one another on a carrier 170. Each row may, as shown in FIG. 7, comprise four components 104 or alternatively a different, or greater, number of components 104.

In an optoelectronic component 104, in contrast to the component 101, the conversion element 130 and the semiconductor chip 120 located underneath are arranged in the region of the three side walls 114, 115, 116 adjoining one another. The conversion element 130 therefore has an exposed edge section 134, 135, 136 at each of the three side walls 114, 115, 116. The three edge sections 134, 135, 136, which respectively meet at a right angle, respectively form a part of one of the side walls 114, 115, 116. In this case, the front-side emission surface 131 in the region of the three side walls 114, 115, 116 forms a part of the edge of the front side 111. In a component 104, the reflective layer 150 is present only in a region extending from the conversion element 130 (and the semiconductor chip 120) to the side wall 117. Only at this position does the reflective layer with a front-side section form a part of the front side 111.

In each of the two rows, the associated optoelectronic components 104 have the same lateral alignment and are aligned with the side walls 115, 117 along the extent direction of a row so that the emission surfaces 131 have a small spacing from one another. The side walls 114, 116 of neighboring components 104 in each row face toward one another. The effect of this is that, in each row, the edge sections 134, 136 of conversion elements 130 of neighboring components 104 respectively are opposite to one another. In this way, it can respectively be made possible that at least a part of the light radiation emitted laterally through an edge section 134 or 136 of a conversion element 130 can reach the opposite edge section 136 or 134 of the neighboring conversion element 130 and enter into the relevant conversion element 130. In this way, efficiency losses can be avoided or restricted.

In addition, the conversion elements 130 and therefore the emission surfaces 131 of the optoelectronic components 104 of the two different rows are also arranged with a small spacing from one another. To this end, the two rows of components 104 are aligned parallel or antiparallel to one another. Furthermore, the side walls 115 and the edge sections 135, present here, of conversion elements 130 of neighboring components 104 of the different rows are respectively opposite to one another. In this way, it is respectively possible that at least a part of the light radiation emitted laterally through an edge section 135 of a conversion element 130 can reach the opposite edge section 135 of the neighboring conversion element 130 and enter into the relevant conversion element 130.

The lighting device 194 may also be formed with reflective components 180 to permit back-reflection at the optoelectronic components 104 present at the end of the two rows. As indicated in FIG. 7, a single reflective component 180 may respectively be arranged at the end of the two rows, the reflective layer 150 of which is opposite to the edge sections 114, 116 of two conversion elements 130 of the different rows so that reflection back to the edge sections 134, 136 can be induced.

The lighting device 194 shown in FIG. 7 may be a relatively compact light source. In this case, the light-emitting conversion elements 130 of the optoelectronic components 104 are bounded laterally outward by the reflective layers 150 of the optoelectronic components 104 and of the reflective components 180.

Besides the examples described with the aid of FIGS. 5 to 7, further examples may be envisioned. For example, an optoelectronic component may be implemented in which the conversion element 130 and the semiconductor chip 120 located underneath are arranged at one or more other side walls. One possible example is a component in which, in contrast to the component 101, the conversion element 130 is arranged at the two opposite side walls 114, 116. In this configuration, the conversion element 130 has, in a manner comparable to the component 104, both an exposed edge section 134 at the side wall 114 and an exposed edge section 136 at the side wall 116, and the front-side emission surface 131 therefore forms a part of the edge of the front side 111 at these opposite positions. In such a component, the reflective layer 150 may be present in two separate regions, one region extending as in the component 104 from the conversion element 130 (and the semiconductor chip 120) to the side wall 117, and a further region extending from the conversion element 130 (and the semiconductor chip 120) to the side wall 115. In these two regions, a front-side section of the reflective layer 150 may respectively form a corresponding part of the front side 111. The emission surface 131, present in between, of the conversion element 130 forms the remaining part of the front side 111. A lighting device may be implemented with a plurality of such components arranged next to one another in the form of a row. In this case, the components, in a manner comparable to the lighting device 194, may have the same lateral alignment and be positioned such that side walls 114, 116 and therefore exposed edge sections 134, 136, of conversion elements 130 of neighboring components are opposite one another. A reflective component 180 may respectively be used at the two row ends.

Particularly in relation to the lighting device 194 of FIG. 7, one possible variant consists of forming a reflective layer 150 additionally between the optoelectronic components 104 and around them. The additional reflective layer 150 may comprise the same material as or a material comparable to the reflective layer 150 of the individual optoelectronic components 104, i.e., an encapsulation material filled with reflective particles. In this configuration, the reflective components 180 may be omitted.

To illustrate this variant, FIG. 7 indicates with the aid of dashed lines a region 151 within which the additional reflective layer 150 may be provided on the carrier 170. By this additional reflective layer 150, which may extend as far as the front sides 111 of the optoelectronic components 104, it is possible to achieve the effect that light radiation generated by the components 104 is emitted only through the front-side emission surfaces 131 of the conversion elements 130. Light radiation emerging at the edge sections 134, 135, 136 of the conversion elements 130 can be reflected back again by the additional reflective layer 150 into the conversion elements 130 so that no lateral light emission takes place.

Such a configuration may be implemented in that, after mounting of the optoelectronic components 104 on the carrier 170, intermediate regions between the components 104 and regions around the components 104 are filled with a particle-filled encapsulation material to form the reflective layer 150. To this end, for example, a frame enclosing the components 104, or the filling region 151 may be arranged on the carrier 170 or the carrier 170 may be provided with such a frame. Provision of an additional reflective layer 150 between optoelectronic components and around these, with the aim of avoiding lateral light emission, may also be envisaged for the other lighting devices described above, for example, the lighting device 193 of FIG. 6.

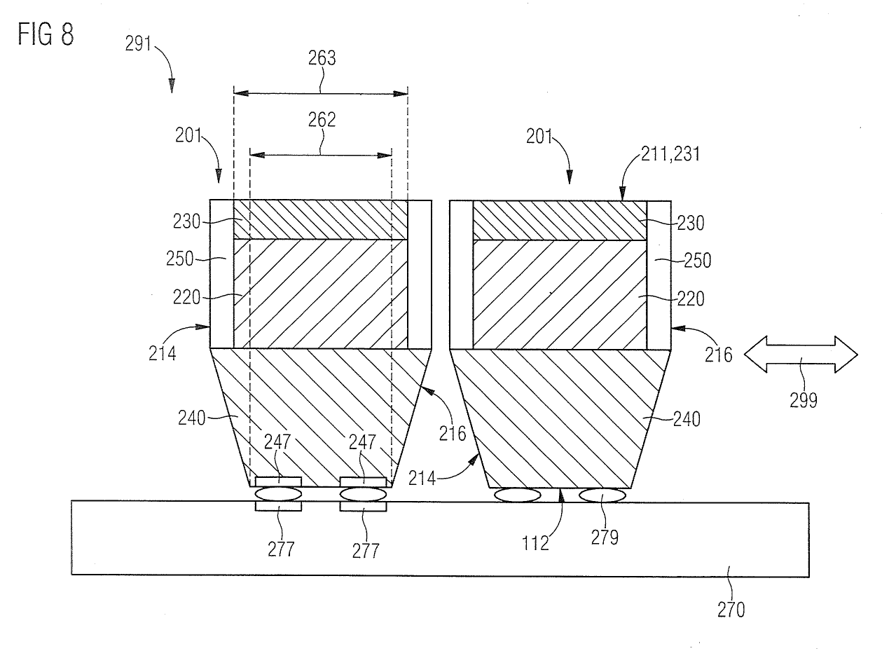

A further concept of allowing small spacings of emission surfaces 231 of optoelectronic components arranged next to one another will be described on the basis of FIGS. 8 to 13. The optoelectronic components have a similar structure to the components described above. In this case, provision is made to configure an optoelectronic component such that, in a cross section of the component, a width of the emission surface 231 provided at the planar front side is greater than or at least as large as a width of a rear side, opposite to the front side, of the component. In this way, it is likewise possible to achieve a reduction or minimization of the spacings of the emission surfaces 231.

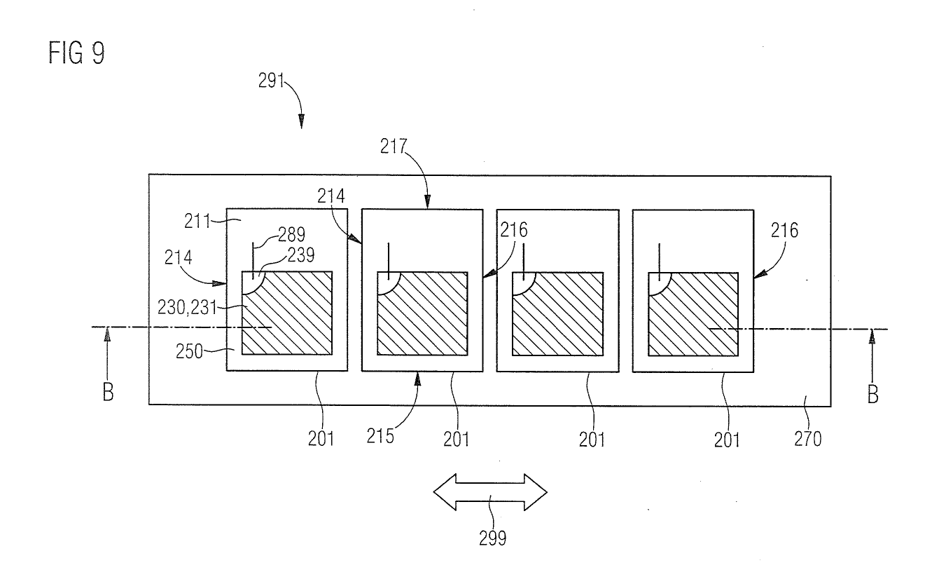

FIGS. 8 and 9 show, in a lateral sectional representation and in a plan view representation, an example of a lighting device 291 comprising a plurality of optoelectronic components 201 having this width configuration. The sectional representation of FIG. 8 relates to the section plane indicated in FIG. 9 with the aid of the section line B-B. In what follows, the configuration of an optoelectronic component 201 will first be described in more detail. This description relates to all the components 201 provided in the lighting device 291. The optoelectronic component 201 comprises components comparable to the component 101 so that details described above for parts which are the same or have the same effect may also be used for the component 201.

The optoelectronic component 201 has, as is shown in plan view in FIG. 9, a rectangular shape with sides of different lengths, i.e., two mutually opposite first longer sides 214, 216 and two mutually opposite second shorter sides 215, 217. These will also be referred to below as long sides 214, 216 and short sides 215, 217. The component 201 furthermore comprises, as represented in FIG. 8, two opposite end sides 211, 212, referred to below as the front side 211 and the rear side 212, between which extend the other sides 214, 215, 216, 217 used as side walls.

Because of the rectangular shape, the optoelectronic component 201 as seen from above can be assigned two mutually perpendicularly extending lateral extent directions. In this case, one extent direction is defined by the short sides 215, 217, and a further extent direction perpendicular thereto is defined by the long sides 214, 216. The lateral extent along the short sides 215, 217 will also be referred to below as the transverse extent, and the extent along the long sides 214, 216 as the length extent. The cross section shown in FIG. 8 therefore relates to the transverse extent direction of the component 201.

The optoelectronic component 201 has a carrier substrate 240 acting as a base, a single optoelectronic semiconductor chip 220 for radiation generation arranged on the carrier substrate 240, a platelet-shaped conversion element 230 for radiation conversion, or surface conversion, arranged on the semiconductor chip 220, and a reflective layer 250 arranged on the carrier substrate 240. The reflective layer 250 used for radiation reflection adjoins the semiconductor chip 220 and the conversion element 230. The semiconductor chip 220 and the conversion element 230 are, in particular, enclosed at the edge fully, or over the entire circumference, by the reflective layer 250.

The optoelectronic semiconductor chip 220 may in particular be a light-emitting diode chip, or LED chip. The latter may, for example, be in the form of a thin-film chip. The semiconductor chip 220 is configured to generate primary light radiation when electrical energy is supplied. The primary radiation may be emitted substantially through a light exit side, or light exit surface, on which the conversion element 230 is directly arranged, of the semiconductor chip 220. The semiconductor chip 220 and its light exit side have a rectangular shape in plan view.

To supply electrical energy to the optoelectronic semiconductor chip 220, the semiconductor chip 220 is configured with two electrical contacts. In this case, the semiconductor chip 220 has a front-side contact in the region of the light exit side and a rear-side contact at the opposite rear side (not represented).

The carrier substrate 240 has, on a front side on which the semiconductor chip 220 and the reflective layer 250 are arranged, a mating contact adapted to the rear-side contact of the semiconductor chip 220. These two contacts may be connected to one another by a solder so that the semiconductor chip 220 is electrically and mechanically connected (not represented) to the carrier substrate 240. For the front-side contact of the semiconductor chip 220, which is arranged at the edge or at a corner of the semiconductor chip 220, the carrier substrate 240 has a further mating contact on its front side (not represented). These two contacts are electrically connected by a bonding wire 289 embedded in the reflective layer 250 (cf. FIG. 9).

The carrier substrate 240, which is rectangular in plan view may, for example, be a ceramic carrier substrate. A rear side, opposite the front side of the carrier substrate 240, forms the rear side 212 of the optoelectronic component 201. At this side 212, the carrier substrate 240 has two electrical connections 247 (only shown for the left-hand component 201 in FIG. 8). The connections 247, which are, for example, in the form of solder surfaces may, for example, have a strip shape and extend parallel to the long sides 214, 216 of the component 201. The connections 247 are electrically connected to the mating contacts present at the front side of the carrier substrate 240.

The platelet-shaped conversion element 230 may, for example, be fastened (not represented) with the aid of a transparent adhesive, for example, a silicone adhesive on the light exit side of the semiconductor chip 220. The conversion element 230 is configured to convert at least a part of the primary radiation generated by the semiconductor chip 220 during operation into lower-energy conversion radiation. To this end, the conversion element 230 comprises a suitable conversion material which can absorb the primary radiation and be excited to re-emit the conversion radiation. In this way, it is possible to generate mixed radiation consisting of primary radiation and conversion radiation which can be emitted by the conversion element 230. It is also possible for the conversion element 230 to convert substantially all of the primary radiation into the conversion radiation and emit the latter. The conversion element 230 may, for example, be a ceramic conversion element 230.

The conversion element 230, which may have the same or substantially the same lateral dimensions as the semiconductor chip 220 or its light exit side, is positioned congruently over the light exit side. The conversion element 230 may also have larger lateral dimensions. The conversion element 230 has a substantially rectangular plan view shape comparable to the semiconductor chip 220. At one corner, the conversion element 230 has a recess 239 adapted to the front-side contact of the semiconductor chip 220 to permit contacting of the front-side contact with the bonding wire 289 (cf. FIG. 9). In the cross section shown in FIG. 8, the conversion element 230 has a rectangular shape. In a section plane extending perpendicularly thereto, the conversion element 230 likewise has a rectangular shape (not represented).

The optoelectronic component 201 may, for example, be a white light source. To this end, the semiconductor chip 220 may be configured to generate primary radiation in the blue to ultraviolet spectral range, and the conversion element 230 may be configured to generate conversion radiation in the yellow spectral range. As an alternative, the conversion element 230 may have different conversion materials to generate conversion radiation comprising a plurality of radiation components, in the case of blue-violet primary radiation, for example, a yellow-green radiation component and a red radiation component. The component 201 may furthermore be configured to emit non-white light radiation, for example, yellow light radiation.

During operation of the optoelectronic component 201, the light radiation is emitted through the conversion element 230. The light emission takes place through the extensive front side 231, located at the front side 211 of the component 201, of the conversion element 230. This will be referred to below as the luminous or emission surface 231. The emission surface 231 forms a part of the front side 211 of the component 201.

The reflective layer 250 used in the optoelectronic component 201 for radiation reflection and partially embedding the semiconductor chip 220 and the conversion element 230 is made of an encapsulation material, for example, silicone with reflective particles, for example, of titanium oxide contained therein. The reflective layer 250 extends as far as the front side 211 of the component 201 and, with a front-side section which adjoins the emission surface 231 and encloses the emission surface 231 fully, or in the shape of a frame, forms a further (remaining) part of the front side 211. The conversion element 230 and the semiconductor chip 220 located underneath are fully enclosed at the edge by the reflective layer 250. In this configuration, for the conversion element 230, only the front-side emission surface 231 is uncovered. During operation of the component 201, light radiation can consequently be emitted only through the emission surface 231. Light radiation emitted laterally through the edge of the conversion element 230 can be reflected back again into the conversion element 230 with the aid of the reflective layer 250.

The optoelectronic component 201 is configured such that a cross-sectional width 263 of the emission surface 231 of the conversion element 230 is greater than a cross-sectional width 262 of the rear side 212 of the component 201. This width configuration is present in the cross section illustrated in FIG. 8, which relates to the transverse extent direction of the component 201. As indicated above, the transverse extent direction is directed along the short sides 215, 217 of the component 201.

In the optoelectronic component 201, the aforementioned width feature is implemented in that the carrier substrate 240 as shown in FIG. 8, has a cross-sectional shape widening from the rear side 212 in the direction of the front side 211. In this case, the carrier substrate 240 has a trapezoidal shape with sides extending obliquely with respect to the front and rear sides 211, 212 of the component 201. This configuration is present in the transverse extent direction of the component 201. In relation to the longitudinal extent direction of the component 201 along the long sides 214, 216, conversely, the carrier substrate 240 may have a rectangular cross-sectional shape (not represented).

The effect of the cross-sectional shape of the carrier substrate 240, which is trapezoidal in the transverse extent direction, is that in the optoelectronic component 201 the long sides 214, 116 extending between the front and rear sides 211, 212 are not in the shape of a planar side wall but are respectively composed of two wall sections extending obliquely with respect to one another (i.e., a section formed by the carrier substrate 240 and extending obliquely with respect to the front and rear sides 211, 212, and a section formed by the reflective layer 250 and extending perpendicularly to the front and rear sides 211, 212). The short sides 215, 217, conversely, may be present as planar side walls extending perpendicularly between the front and rear sides 211, 212. The component 201 therefore has a cuboid shape only in a region between the front side 211 and the carrier substrate 240.

In a production method, a plurality of optoelectronic components 201 may be fabricated together or in parallel. In this case, a continuous carrier substrate 240, on which a plurality of semiconductor chips 220, and conversion elements 230 thereon, is arranged, may be provided for a plurality of components 201. After connection of bonding wires 289 to front-side contacts of the chips 220 and mating contacts of the continuous carrier substrate 240, regions between the semiconductor chips 220 and conversion elements 230 and, around these, may be filled with a particle-filled encapsulation material to form the reflective layer 250. At the end of the production method, a separation process may be carried out to provide separate optoelectronic components 201. In the scope of the separation process, which may comprise cutting or sawing, the widening or slanted cross-sectional shape of the carrier substrate 240 may be produced.

The structure of the optoelectronic component 201 offers the possibility of arranging a plurality of such components 201 next to one another such that the front-side emission surfaces 231 of neighboring components 201 have a small spacing from one another. This aspect will be explained with the aid of the lighting device 291 shown in FIGS. 8 and 9 comprising a group of a plurality of optoelectronic components 201 arranged next to one another. Two of the four components 201 shown in FIG. 9 are shown in FIG. 8. It is possible for the lighting device 291 to have a different, in particular larger, number of components 201. The lighting device 291 may, for example, be part of a vehicle headlamp.

The lighting device 291 comprises a relatively large carrier 270 on which the optoelectronic components 201 are arranged in the form of a row next to one another (1D arrangement). An arrangement or extent direction 299 of the row is indicated with the aid of a double arrow in FIGS. 8 and 9. The carrier 270, which may be a circuit board, comprises electrical connections 277 adapted to the rear-side electrical connections 247 of the optoelectronic components 201. The connections 247, 277 may be connected to one another by a solder 279, as shown for the left-hand component 201 in FIG. 8. Fixing of the components 201 on the carrier 270 may, for example, be carried out with the aid of an SMT mounting method in which a reflow solder process is carried out. The connections 277 provided for the components 201 of the carrier 270 may be present in a predetermined spacing grid so that the spacings of the component 201 on the carrier 270 are established.

In the lighting device 291, the optoelectronic components 201 respectively have the same lateral alignment and are arranged next to one another along the transverse extent direction of the components 201. In this case, the long sides 214, 216 of respectively two neighboring components are opposite to one another. In this arrangement, the transverse extent direction of the components 201 coincides with the extent direction 299 of the row, or defines the extent direction 299 of the row. With such alignment, the conversion elements 230 and therefore the emission surfaces 231 of the individual components 201 have a small spacing from one another.

In a conventional single-chip component, an emission surface may have a smaller cross-sectional width in the transverse extent direction compared with the rear side. The effect of aligning such components is therefore that the emission surfaces are spaced apart further than the rear sides.

The configuration, differing therefrom, of the optoelectronic component 201 with the emission surface 231 wider than the rear side 212 in the transverse extent direction, conversely, has the effect that in the lighting device 291 the spacing of the emission surfaces 231 between two neighboring components 201 is less than the spacing between the rear sides 212 of the components 201. In the lighting device 291, the emission surfaces 231 of neighboring components 201 consequently have relatively small spacings from one another so that there can be a more homogeneous luminous surface formed from the emission surfaces 231.

Because of the trapezoidal shape of the carrier substrates 240, not only the rear sides 212 themselves but also subregions of the carrier substrates 240 which are adjacent to the rear sides 212 can have relatively large spacings. It is therefore optionally possible to use such a carrier 270 in which the connections 277 are present in a spacing grid which is smaller than in the case of a carrier provided for conventional components. The trapezoidal configuration offers the possibility, even when there are uneven surfaces due to production, of avoiding contact of neighboring components 201 in the lower region of the carrier substrates 240. Close positioning of emission surfaces 231 can be favored in this way. Furthermore, the carrier substrates 240 of the optoelectronic components 201 can have a larger manufacturing tolerance than the conversion elements 230.

In one possible variant, the optoelectronic component 201 or its carrier substrate 240 may optionally be configured such that the front-side emission surface 231 and the rear side 212 have a matching cross-sectional width 262, 263.

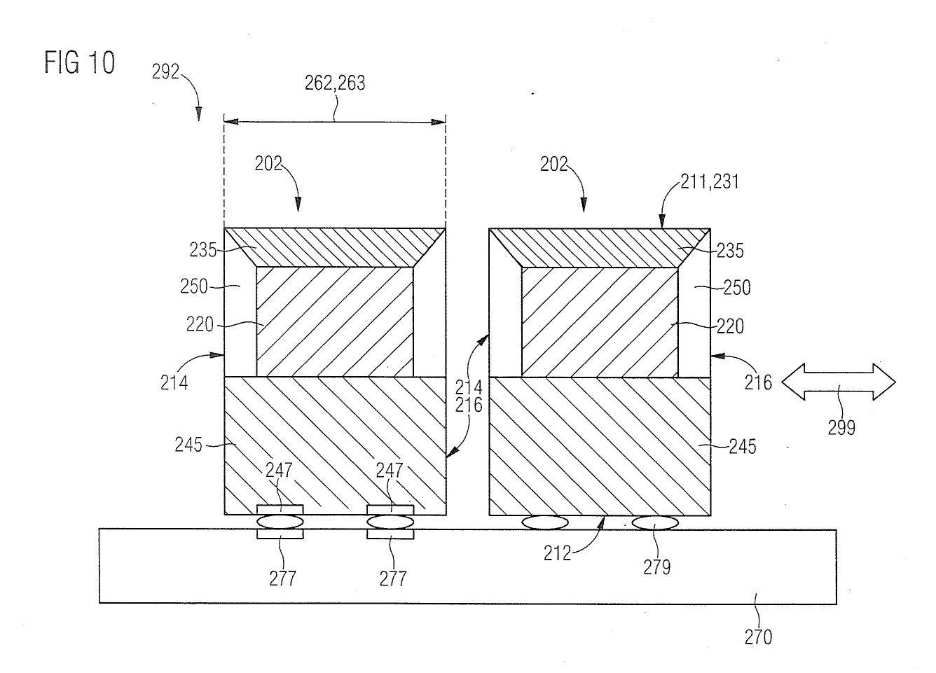

With the aid of the following FIGS. 10 to 13, further examples of optoelectronic components and lighting devices will be described. The optoelectronic components are configured in a manner comparable to the component 201 such that a front-side emission surface 231 is at least as wide as a rear side 212 in cross section. In the same way, the optoelectronic components comprise a carrier substrate 240, 245, a semiconductor chip 220 arranged on the carrier substrate 240, 245, a conversion element 230, 235, 236 arranged on the semiconductor chip 220, and a reflective layer 250 arranged in addition to the semiconductor chip 220 and the conversion element 230, 235, 236 on the carrier substrate 240, 245. In an associated lighting device, as in the lighting device 291, the components are arranged next to one another in relation to a transverse extent direction of the components. In relation to details already described which relate to parts and features which are of the same type or correspond to one another, production, possible advantages or the like, reference is made to the description above. In particular, carrier substrates 245 and conversion elements 235, 236 of the components described below may differ merely by the shape of the carrier substrate 240 and the conversion element 230 of the component 201. Details mentioned in relation to one of the following examples may also apply to other examples.

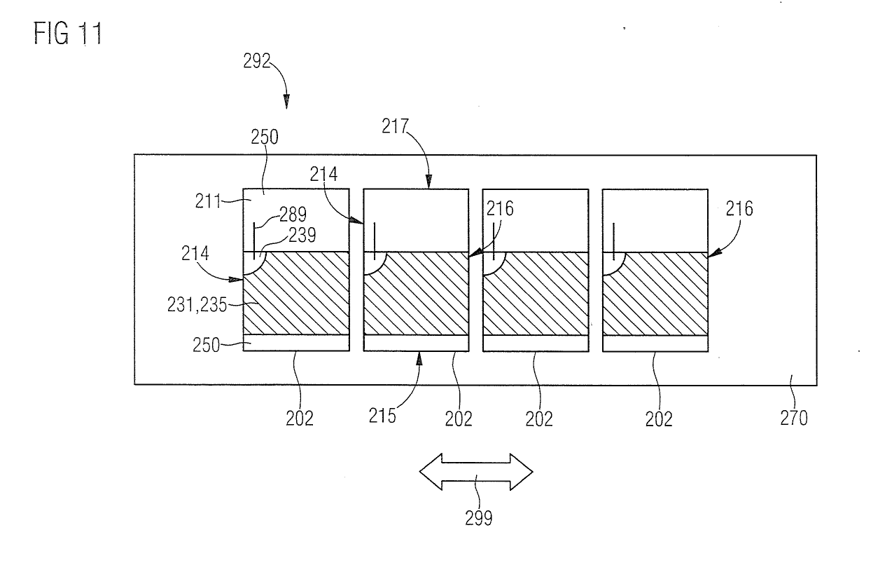

FIGS. 10 and 11 show a further lighting device 292 in a lateral sectional representation and in a plan view representation. The lighting device 292 comprises a plurality of optoelectronic components 202, which are arranged in the form of a row next to one another on a carrier 270. Instead of the four components 202 shown in FIG. 11, the lighting device 292 may have a different, in particular larger, number of components 202. The configuration of a component 202 will be discussed first below.

In contrast to the component 201, the optoelectronic component 202 is configured in the shape of a cuboid. The component 202 again has two opposite long sides 214, 216 and short sides 215, 217. In contrast to the component 201, the long sides 214, 216 like the short sides 215, 217 are present as planar side walls extending perpendicularly between the front and rear sides 211, 212 of the component 202. The component 202 has a carrier substrate 245 provided with rear-side connections 247 and, in contrast to the carrier substrate 240, is configured in the shape of a cuboid. The carrier substrate 245 therefore has a rectangular shape in the cross section shown in FIG. 10, which here again relates to a transverse extent of the component 202 defined by the short sides 215, 217.

The optoelectronic component 202 comprises a platelet-shaped conversion element 235 for surface conversion, arranged on the semiconductor chip 220. As shown in FIG. 10, the conversion element 235 has a cross-sectional shape widening from a rear side of the conversion element 235 in the direction of a front-side emission surface 231. In this case, the conversion element 235 has a trapezoidal shape with edge sides extending obliquely with respect to its front and rear sides and, therefore, with respect to the front and rear sides 211, 212 of the component 202. This slanted configuration is present in the transverse extent direction of the component 202. In relation to the longitudinal extent direction of the component 202 along the long sides 214, 216, conversely, the conversion element 235 may have a rectangular cross-sectional shape (not represented). The conversion element 235 also has, as seen from above, a substantially rectangular geometry with a recess 239 adapted to the front-side contact of the semiconductor chip 220 (cf. FIG. 11).

The conversion element 235 is arranged or adhesively bonded with its rear side, which is opposite to the emission surface 231, on the light exit side of the semiconductor chip 220. The rear side of the conversion element 235 may have substantially the same lateral dimensions as or even larger lateral dimensions than the rectangular semiconductor chip 220, or its light exit side. In this case, the conversion element 235 may be arranged with its rear side congruently over the light exit side of the semiconductor chip 220.

The optoelectronic component 202 with the trapezoidal conversion element 235 is furthermore configured such that the front-side emission surface 231 of the conversion element 235 reaches in the transverse extent direction of the component 202 on both sides to the two planar long sides 214, 216 and, therefore, forms a part of the edge of the front side 211 at these positions. In this way, the cross-sectional width 263 of the emission surface 231 of the conversion element 235 coincides with the cross-sectional width 262 of the rear side 212 of the component 202, as shown in FIG. 10.

The reflective layer 250 likewise provided in the optoelectronic component 202, arranged on the carrier substrate 245 and enclosing the semiconductor chip 220, may also reach as far as the conversion element 235 in this configuration and enclose the conversion element 235 at the edge side. Since the emission surface 231 of the conversion element 235 in the present case adjoins the two sides 214, 216, in contrast to the component 201 the emission surface 231 is no longer fully enclosed by a single circumferential front-side section of the reflective layer 250. In the component 202, the front side 211 is formed by two separate front-side sections of the reflective layer 250 and the emission surface 231 arranged in between (cf. FIG. 11).

In the conversion element 235, however, only the emission surface 231 is still exposed, while the edge present between the emission surface 231 and the rear side of the conversion element 235 or corresponding edge sides of the conversion element 235, are enclosed by the reflective layer 250. It is therefore possible that light radiation is emitted only through the emission surface 231 of the conversion element 235 during operation of the optoelectronic component 202. It may possibly happen that, because of the trapezoidal shape of the conversion element 235 and consequently the cross-sectional width of the reflective layer 250 decreasing in the direction of the front side 211, minor lateral light emission also takes place in the region of the long sides 214, 216.

In a manner comparable to the lighting device 291, in the lighting device 292 the optoelectronic components 202 used here are also arranged with a matching lateral alignment and next to one another along their transverse extent direction. In this case, the long sides 214, 216 of respectively two neighboring components 202 face toward one another. The transverse extent direction of the components 202 therefore again coincides with the extent direction 299 of the row. Since the emission surfaces 231 and the rear sides 212 in the components 202 have a matching cross-sectional width 262, 263, there are correspondingly equally large spacings between the emission surfaces 231 and the rear sides 212. Compared to alignment of conventional components, the front-side emission surfaces 231 of neighboring components 202 may therefore have small(er) spacings from one another.

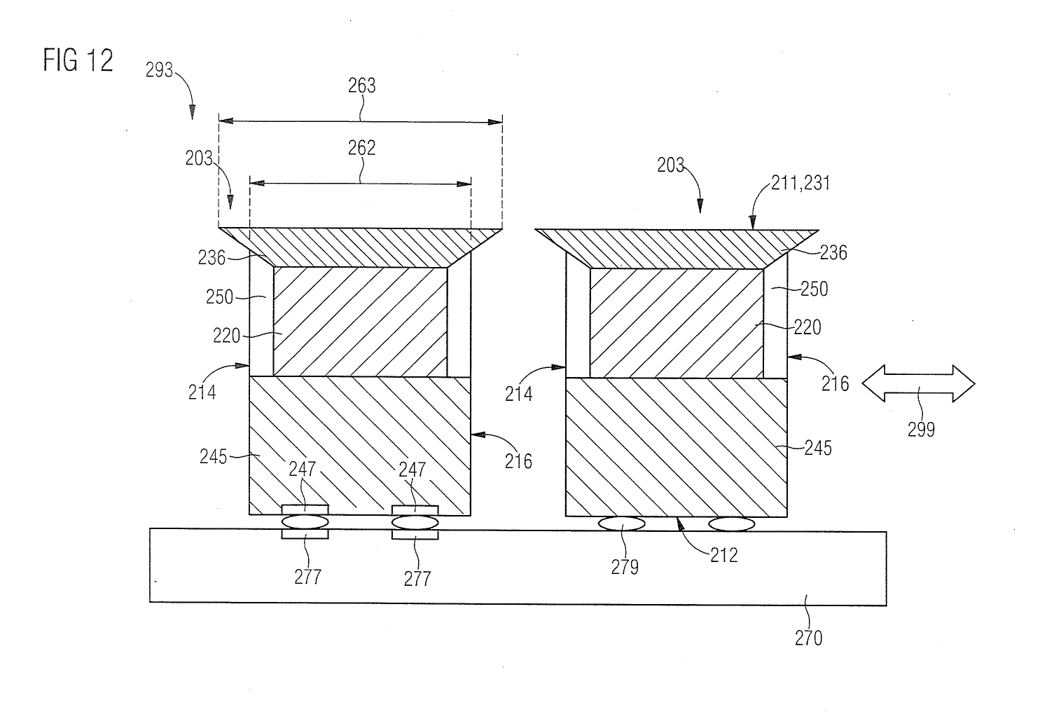

FIG. 12 shows a lateral sectional representation of a lighting device 293 having optoelectronic components 203 arranged in the form of a row next to one another on a carrier 270. The components 203 of the lighting device 293 represent a refinement of the component 202 described above. Each of the components 203 has a platelet-shaped conversion element 236 arranged on the semiconductor chip 220 and, like the conversion element 235, is configured trapezoidally in cross section with a cross-sectional shape widening from a rear side of the conversion element 236 in the direction of the front-side emission surface 231. This configuration is present in the transverse extent direction of the component 203. In relation to the longitudinal extent direction, the conversion element 236 may have a rectangular cross-sectional shape (not represented).

In the conversion element 236, the rear side may have the same dimensions as or even larger dimensions than the rectangular semiconductor chip 220, or its rectangular light exit side, and the rear side of the conversion element 236 may be positioned congruently over the light exit side of the semiconductor chip 220. In plan view, the conversion element 236 may have a substantially rectangular geometry and a recess (not represented) adapted to the front-side contact of the semiconductor chip 220.

The optoelectronic component 203 differs from the component 202 in that the trapezoidal conversion element 236 laterally protrudes or overhangs in the region of the front side 211. In this way, in relation to the transverse extent of the component 203, the cross-sectional width 263 of the emission surface 231 of the conversion element 236 is greater than the cross-sectional width 262 of the rear side 212 of the cuboid carrier substrate 245 and, therefore, of the component 203. Because of this, as seen from above, the component 203 no longer has the rectangular front side 211, shown in FIG. 11, present in the component 202, but because of the conversion element 236 laterally overhanging at the long sides 214, 216, it has a front side 211 with a cross-shaped geometry. The front side 211 is here again formed by two separate front-side sections of the reflective layer 250 reaching to the conversion element 236 and of the emission surface 231 arranged in between (not represented).

The overhanging shape provided in the optoelectronic component 203 furthermore has the effect that the reflective layer 250 in the cross section shown in FIG. 12 no longer extends as far as the front-side emission surface 231. The edge sides, extending obliquely in this region, of the conversion element 236 are therefore only partly enclosed by the reflective layer 250 and are partially exposed. The effect of this is that, during operation of the component 203, the conversion element 236 can emit light radiation not only through the emission surface 231 but in addition also through the exposed edge sides.

The lighting device 293 is in other regards configured in a manner comparable to the lighting device 292. The optoelectronic components 203 are again arranged next to one another along their transverse extent direction, which coincides with the extent direction 299 of the row. The effect of the overhanging configuration or the emission surfaces 231 which are wider in cross section in comparison with the rear sides 212 is that the lighting device 293 can be configured with even smaller spacings of the emission surfaces 231 of neighboring components 203 compared to the lighting device 292.

In the lighting device 293, but also in the lighting device 292, lateral emission of light radiation may take place. Between respectively two neighboring optoelectronic components 202, 203, light radiation emitted laterally by a conversion element 235, 236 may be optionally partly coupled into a neighboring conversion element 235, 236. In relation to lateral light emission respectively taking place at the end of a row, it is possible to neglect the loss associated therewith. As an alternative, in a manner comparable to the concept presented above with the aid of FIGS. 1 to 7, it is possible to provide back-reflection for a component 202, 203 present at a row end. To this end, a reflective component comprising a carrier substrate and a reflective layer 250 may be arranged next to the relevant optoelectronic component 202, 203 to reflect the laterally emitted light radiation back at least partially (not represented). It is furthermore possible to arrange an additional reflective layer at least in intermediate regions between the components 202, 203.

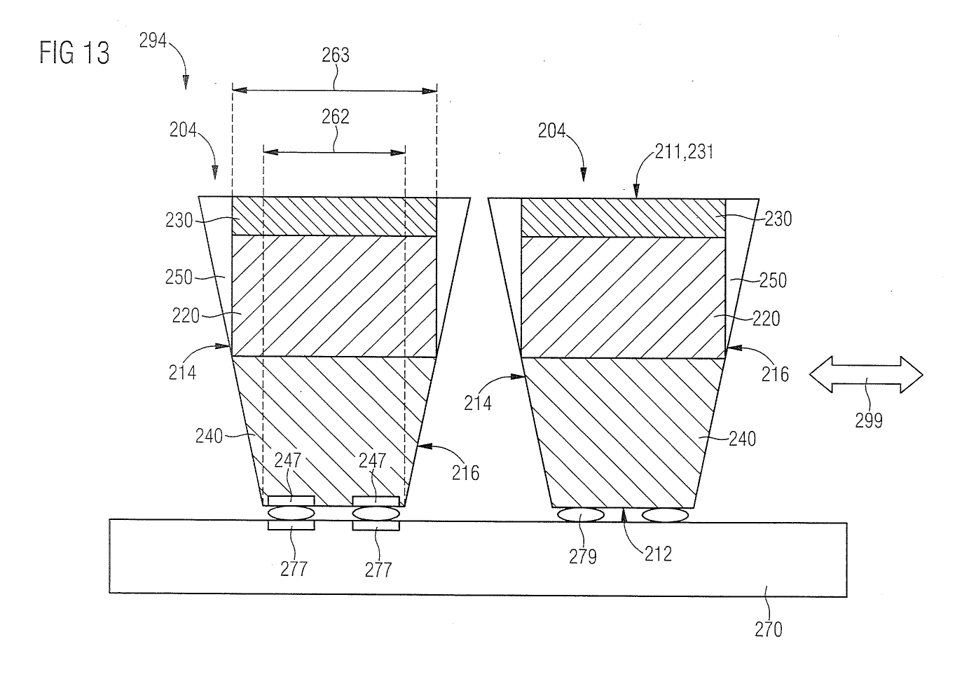

FIG. 13 shows a lateral sectional representation of a lighting device 294 with optoelectronic components 204, which are arranged in the form of a row next to one another on a carrier 270. The components 204 of the lighting device 294 represent a variant of the component 201 shown with the aid of FIGS. 8 and 9. In each of the components 204, there is not just a trapezoidal carrier substrate 240. Rather, the entire component 204 has a cross-sectional shape widening from the rear side 212 in the direction of the front side 211 in cross section. In this case, each component 204 has a trapezoidal shape with side walls or long sides, 214, 216 extending obliquely with respect to the front and rear sides 211 in cross section, 212. This configuration is present in the transverse extent direction of the component 204. In relation to the longitudinal extent direction, the component 204 may have a rectangular cross-sectional shape, and therefore have short sides 215, 117 extending perpendicularly to the front and rear sides 211, 212 (not represented). The configuration, which is trapezoidal in cross section, may be formed in the scope of a separation process which is carried out during the common production of a plurality of components 204.

In plan view, the optoelectronic component 204 may correspond to the component 201 so that the representation shown in FIG. 9 may also apply for the component 204 (and therefore the lighting device 294). In this case, the front-side emission surface 231 of the conversion element 230 is fully enclosed by a front-side section of the reflective layer 250. The edge of the conversion element 230 is also fully enclosed by the reflective layer 250 so that only the front-side emission surface 231 is exposed. Light radiation can therefore be emitted only through the emission surface 231 during operation of the component 204.

In the optoelectronic component 204, in relation to the transverse extent of the component 204, the cross-sectional width 263 of the emission surface 231 of the conversion element 230 is likewise greater than the cross-sectional width 262 of the rear side 212 of the component 204. In the lighting device 294 formed from a plurality of components 204, the emission surfaces 231 of neighboring components 204 can therefore have a small spacing from one another. As shown in FIG. 13, in the lighting device 294 the components 204 are also arranged with a matching lateral alignment and next to one another along their transverse extent direction. In this case, the transverse extent direction of the components 204 again coincides with the extent direction 299 of the row, and the long sides 214, 216 of respectively two neighboring components 204 are opposite to one another.

In the optoelectronic components 204 arranged next to one another, not only the rear sides 212 themselves but also further subregions of the trapezoidal components 204 may be spaced relatively far apart from one another. It is therefore possible to use a carrier 270 with a smaller spacing grid of the connections 277 compared with a conventional carrier to favor close positioning of emission surfaces 231. In particular, in this configuration it is possible to avoid contact of neighboring components 204 when there are uneven surfaces due to production.

A trapezoidal optoelectronic component may also be configured with a different cross-sectional shape. For example, a cross-sectional shape similar to FIG. 13 may be provided, but unlike in FIG. 13 with the front side of the carrier substrate 240 being wider than the rear side of the semiconductor chip 220 so that a part of the reflective layer 250 may be present laterally with respect to the rear side of the semiconductor chip 220. A further variant consists in the semiconductor chip 220 also having in cross section a (partially) slanted cross-sectional shape starting from its rear side.

Besides the examples described with the aid of FIGS. 8 to 13, further examples may be envisioned. Instead of trapezoidal shapes, for example, other widening cross-sectional shapes, for example, with curved, for example, concave contours may be provided for carrier substrates, conversion elements and optoelectronic components. It is also possible for there to be a plurality of subregions widening differently in cross section or for there to be only partial widening so that besides one or more widening subregions there may also be one or more other subregions with a constant cross-sectional width. It is furthermore possible to combine different variants so that, for example, there is a widening carrier substrate or a widening cross-sectional shape of a component together with a widening conversion element.

Furthermore, on the basis of the concept described with the aid of FIGS. 8 to 13, in the same way two rows, or 2D arrangements of optoelectronic components may also be implemented. In this case, the two rows of components may be arranged parallel or antiparallel to one another so that sides or short sides of neighboring components of the different rows are opposite to one another. In this context, it is optionally possible to provide sides for carrier substrates, conversion elements and/or components which also do not extend perpendicularly to a front and rear side in the region of the sides facing one another, but instead, e.g., obliquely extending sides differing therefrom to favor close positioning of emission surfaces of components of the different rows.

Optoelectronic components having an at least partially widening cross-sectional shape may be implemented with a carrier substrate having an at least partially widening cross-sectional shape and/or with a conversion element having an at least partially widening cross-sectional shape, optionally also independently of the width configuration (the cross-sectional width of an emission surface is at least as large as a rear-side cross-sectional width). Apart from the width configuration, there may be features as presented above in the same way in the components.

The examples explained with the aid of the figures represent preferred examples. Besides the examples described and illustrated, further examples may be proposed which comprise further variants or combinations of features. For example, optoelectronic components with different shapes, geometries and structures may be formed, and other materials may be used instead of the materials specified above. Optoelectronic components may also be formed to emit light radiation with a different color or spectral ranges mentioned above may be replaced with other spectral ranges.

In relation to the conversion elements 130, 230, 235, 236, it is possible for them not to be in the form of ceramic conversion elements. One possible alternative is a configuration consisting of a glass material or of a polymer material, or silicone, with embedded luminescent particles for radiation conversion.

Variants may also be envisioned in relation to an optoelectronic semiconductor chip 120, 220. For example, it is possible to use semiconductor chips 120, 220 which only have two rear-side contacts. A carrier substrate 140, 240, 245 may comprise mating contacts adapted thereto on its front side. Connection between the rear-side contacts and the mating contacts may be established by a solder. Connection by a bonding wire 189, 289, as described above, may be omitted in this configuration. It is therefore possible to use conversion elements which, unlike the conversion elements 130, 230, 235, 236, do not have recesses 139, 239.

In the same way, it is possible to use semiconductor chips 120, 220 which only have two front-side contacts. In this configuration, the front-side contacts may be connected with the aid of two bonding wires to mating contacts, adapted thereto, of a carrier substrate 140, 240, 245. In this case, it is possible to use conversion elements which, unlike the conversion elements 130, 230, 235, 236, have two recesses to permit contacting of the front-side contacts.

Furthermore, the possibility is to be pointed out of configuring optoelectronic components 101, 102, 103, 104, 201, 202, 203, 204 with optoelectronic semiconductor chips which are not thin-film chips. For example, a configuration of the optoelectronic components with volume emitters or flip-chips may be envisioned. If such semiconductor chips are arranged at the edge of the optoelectronic components, or form a part of one or more side wall of the components, as may be the case, for example, for the components 101, 102, 103, 104, efficiency losses due to lateral light emission at an exposed edge section of a semiconductor chip may be suppressed or reduced in the same way according to the approaches above. For example, back-reflection at the reflective layer of a neighboring optoelectronic component or of a neighboring reflective component is possible as well as coupling of the light radiation into a neighboring optoelectronic component. Back-reflection at an additional reflective layer, which may be provided between the optoelectronic components and optionally in a region enclosing the components, is furthermore possible.

Furthermore, it is possible for the optoelectronic components 101, 102, 103, 104, 201, 202, 203, 204 shown in the figures and described as well as possible variants thereof to have further constituents. For example, the components may comprise an additional protective diode arranged on a carrier substrate 140, 240, 245 and connected in antiparallel with the semiconductor chip 120, 220. The protective diode may be arranged in a region between a semiconductor chip 120, 220 and a side, or short side, 117, 217, and be enclosed by the reflective layer 150, 250.

Optoelectronic components may furthermore, in contrast to the examples shown in the figures, be configured with a square plan view shape so that there are respectively equally long sides, or side walls, in plan view.

Although our components have been illustrated and described in detail by preferred examples, this disclosure is not restricted to the examples disclosed, and other variants may be derived therefrom by those skilled in the art, without departing from the protective scope of the appended claims.

1-16. (canceled)

17. An optoelectronic component comprising:
a carrier substrate;
a single optoelectronic semiconductor chip arranged on the carrier substrate;
an emission surface that emits light radiation which is part of a front side of the optoelectronic component; and
a reflective layer adjacent to the emission surface at the front side of the optoelectronic component,
wherein the emission surface is arranged such that the emission surface forms a part of an edge of the front side of the optoelectronic component.

18. The optoelectronic component according to claim 17, further comprising a conversion element for radiation conversion arranged on the semiconductor chip, wherein the conversion element comprises the emission surface that emits the light radiation.

19. The optoelectronic component according to claim 18, wherein the conversion element is arranged at at least one side wall extending from the front side to an opposite rear side of the optoelectronic component so that an edge section of the conversion element forms a part of the side wall of the optoelectronic component.

20. The optoelectronic component according to claim 17, further comprising a plurality of side walls extending from the front side to an opposite rear side, wherein the emission surface is arranged at at least one side wall.

21. The optoelectronic component according to claim 20, wherein the plurality of side walls is planar.

22. A lighting device comprising:
a carrier and a group of a plurality of optoelectronic components according to claim 17, wherein the optoelectronic components of the group are arranged in a row next to one another on the carrier.

23. The lighting device according to claim 22, wherein an edge section of a conversion element of an optoelectronic component of the group is opposite to a reflective layer of a neighboring optoelectronic component of the group.

24. The lighting device according to claim 22, wherein edge sections of conversion elements of two neighboring optoelectronic components of the group are opposite to one another.

25. The lighting device according to claim 22, further comprising two groups of optoelectronic components respectively arranged in a row next to one another on the carrier, wherein edge sections of conversion elements of two neighboring optoelectronic components of the two groups are opposite to one another.

26. The lighting device according to claim 22, further comprising a reflective component having a reflective layer arranged on the carrier such that the reflective layer of the reflective component is opposite to an edge section of a conversion element of an optoelectronic component.

27. The lighting device according to claim 22, further comprising an additional reflective layer arranged on the carrier at least in intermediate regions between the optoelectronic components.

28. An optoelectronic component comprising:
a carrier substrate;
a single optoelectronic semiconductor chip arranged on the carrier substrate;
an emission surface that emits light radiation, which is part of a front side of the optoelectronic component; and
a reflective layer adjacent to the emission surface at the front side of the optoelectronic component,
wherein the emission surface has a cross-sectional width at least as large as a cross-sectional width of a rear side, opposite to the front side, of the optoelectronic component.

29. The optoelectronic component according to claim 28, further comprising a conversion element for radiation conversion arranged on the semiconductor chip, wherein the conversion element comprises the emission surface that emits the light radiation.

30. The optoelectronic component according to claim 29, wherein the conversion element is configured in the shape of a platelet and arranged on a light exit side of the optoelectronic semiconductor chip, in order to permit surface conversion.

31. The optoelectronic component according to claim 29, wherein the conversion element has a cross-sectional shape at least partially widening in the direction of the emission surface.

32. The optoelectronic component according claim 28, wherein the carrier substrate has a cross-sectional shape at least partially widening in the direction of the front side of the optoelectronic component.

33. The optoelectronic component according to claim 28, having a cross-sectional shape at least partially widening in the direction of the front side of the optoelectronic component.

34. A lighting device comprising:
a carrier and a group of a plurality of optoelectronic components according to claim 28, wherein the optoelectronic components of the group are arranged in a row next to one another on the carrier, and wherein, in relation to an extent direction of the row, for each of the optoelectronic components of the group the cross-sectional width of the emission surface is at least as large as the cross-sectional width of the rear side.
